(19) United States
(12) Patent Application Publication
(10) Pub. No.: US 2026/0282678 A1
(43) Pub. Date: Sep. 17, 2026

(54) DISPLAY DEVICE

(71) Applicant: Sharp Display Technology Corporation, Kameyama City, Mie (JP)

(72) Inventors: Tohru OKABE, Kameyama City (JP); Shoji OKAZAKI, Kameyama City (JP); Shinji ICHIKAWA, Kameyama City (JP); Hiroki TANIYAMA, Kameyama City (JP); Eiji FUJIMOTO, Kameyama City (JP)

(21) Appl. No.: 19/469,664

(22) PCT Filed: Apr. 6, 2023
(86) PCT No.: PCT/JP2023/014225

§ 371 Date: Sep. 26, 2025

(51) Int. Cl. H10K 59/131; H10K 59/124

(52) U.S. Cl. CPC H10K 59/131; H10K 59/124

(57) ABSTRACT

A display device includes, in a display area: a plurality of light-emitting elements; a plurality of pixel circuits; and connection wires. The connection wires include a plurality of partial wires formed in mutually different layers via a first organic insulation film of an organic insulating material. The first organic insulation film and a partial wire including the plurality of partial wires are alternately stacked to provide a multilayered structural portion. A second organic insulation film of an organic insulating material is provided on the multilayered structural portion. The display device further includes, in a frame area: a wall body configured to form a groove-shaped depression; and a first wiring line and a second wiring line exposed on a bottom of the depression. The wall body is made of a same material, and provided in a same layer, as the second organic insulation film.

### TECHNICAL FIELD

The present disclosure relates to display devices.

### BACKGROUND ART

Organic EL display devices built around organic electroluminescence (hereinafter, may alternatively be referred to as “EL”) elements have been commercialized. For example, when the organic EL display device is used as a display device for an information terminal such as a smartphone or a tablet terminal and when the organic EL display device is used as a display device in video calls, video conferencing, or like interactive communication, the organic EL display device is combined with an “in-camera”, which is a camera for capturing images of the front side, of the organic EL display device, on which images are displayed.

It is suggested in the organic EL display device combined with an in-camera that the camera is disposed in a position, on the rear side of the organic EL display device, that overlaps the display area of the organic EL display device in a plan view. An example of such an organic EL display device is disclosed in Patent Literature 1.

### CITATION LIST

### Patent Literature

Patent Literature 1: Japanese Unexamined Patent Application Publication No. 2022-041886

### SUMMARY

### Technical Problem

The organic EL display device combined with an in-camera has: a first display area that provides an ordinary display portion; and a second display area, provided internal to the first display area, for transmitting external light used by the camera. The second display area includes connection wires for connecting the organic EL elements to pixel circuits. These connection wires preferably employ a multilayer structure in which partial wires that provide these connection wires and organic insulation films are alternately stacked, for its advantages in increasing layout freedom.

In addition, the organic EL display device employs a structure in which the organic EL elements are covered and sealed with a sealing film. The sealing film used here is a multilayer film in which an inorganic layer and an organic layer are alternately stacked. The organic layer is formed by applying a liquid material by, for example, inkjet printing or using a dispenser and subsequently curing the liquid material. The organic EL display device has a frame area, located externally to the display area, in which there is provided a damming wall. The damming wall is a wall body for damming up the liquid material to stop wet spreading of the liquid material.

When the damming wall is provided in an organic EL display device that has the above-described multilayer structure, the damming wall is constructed of a plurality of wall layers, and the wall layers are formed in combination with a plurality of organic insulation films in the multilayer structure, to simplify the manufacturing process. However, the damming wall could form a groove-shaped depression between the damming wall and the multilayer structure unit. In addition, when two or more damming walls are provided, another depression is formed between adjacent damming walls.

Therefore, to form damming walls together with the multilayer structure, the partial wires are formed with the wall layers, which provide the damming walls, having already been provided. The partial wires are formed by, for example, photolithography. In such a case, if a resist containing a positive photosensitive resin is used in the photolithography, the resist used in the patterning of the partial wires tends to remain in the form of a film (“film residue”) in the depression formed by the damming walls. This film residue of the resist in turn causes an electrically conductive residue to remain in the depression. When a plurality of wires are exposed on the bottom of the depression, these wires are disadvantageously short-circuited with each other via the electrically conductive residue, which creates defects.

The present disclosure has an object to restrain, in a display device in which a plurality of wires are exposed on the bottom of a depression formed by damming walls or like wall bodies, short-circuiting of these wires.

### Solution to Problem

The present disclosure is directed to display devices. A display device in accordance with the present disclosure has: a display area where an image is displayed; and a frame area provided around the display area. The display device includes, in the display area: a plurality of light-emitting elements provided correspondingly to a plurality of subpixels; a plurality of pixel circuits configured to control emission of light by the plurality of light-emitting elements; and connection wires configured to connect the plurality of light-emitting elements and the plurality of pixel circuits respectively. The connection wires include a plurality of partial wires formed in mutually different layers via a first organic insulation film of an organic insulating material. The first organic insulation film and a partial wire including the plurality of partial wires are alternately stacked to provide a multilayered structural portion. A second organic insulation film of an organic insulating material is provided on the multilayered structural portion. The display device further includes, in the frame area: a wall body configured to form a groove-shaped depression along an outer circumference of the display area; and a first wiring line and a second wiring line exposed on a bottom of the depression. The wall body is made of a same material, and provided in a same layer, as the second organic insulation film.

### Advantageous Effects of Disclosure

The technique of the present disclosure can restrain, in a display device in which a first wiring line and a second wiring line are exposed on the bottom of a depression formed by wall bodies, short-circuiting of these first and second wiring lines.

### BRIEF DESCRIPTION OF DRAWINGS

FIG. 1 is a schematic plan view of an exemplary structure of an organic EL display device in accordance with an embodiment.

FIG. 2 is a cross-sectional view of the organic EL display device, taken along line II-II shown in FIG. 1.

FIG. 3 is a plan view of exemplary pixels and various exemplary wires that form a first display area of an organic EL display device in accordance with an embodiment.

FIG. 4 is a cross-sectional view of an organic EL display device, taken along line IV-IV shown in FIG. 3.

FIG. 5 is a cross-sectional view of an exemplary major part of an organic EL display device, surrounded by a circle denoted by V in FIG. 4.

FIG. 6 is an equivalent circuit diagram of an exemplary pixel circuit.

FIG. 7 is a schematic plan view of an exemplary structure of a second display area and its periphery of an organic EL display device in accordance with an embodiment.

FIG. 8 is a plan view of an exemplary major part of an organic EL display device, surrounded by a circle denoted by VIII in FIG. 7.

FIG. 9 is a cross-sectional view of a major part of an organic EL display device, taken along line IX-IX shown in FIG. 8.

FIG. 10 is a cross-sectional view of a major part of an organic EL display device, taken along line X-X shown in FIG. 8.

FIG. 11 is a plan view of an exemplary major part of an organic EL display device, surrounded by a circle denoted by XI in FIG. 1.

FIG. 12 is a cross-sectional view of a major part of an organic EL display device, taken along line XII-XII shown in FIG. 11.

FIG. 13 is a cross-sectional view of a major part of an organic EL display device, taken along line XIII-XIII shown in FIG. 11.

FIG. 14 is a cross-sectional view of a major part of an organic EL display device, taken along line XIV-XIV shown in FIG. 1.

FIG. 15 is a cross-sectional view of an exemplary major part of an organic EL display device, surrounded by a circle denoted by XV in FIG. 12.

FIG. 16 is a cross-sectional view of a part of a process of manufacturing an organic EL display device in accordance with an embodiment.

FIG. 17 is a cross-sectional view of a part of a process of manufacturing an organic EL display device in accordance with an embodiment.

FIG. 18 is a cross-sectional view of a part of a process of manufacturing an organic EL display device in accordance with an embodiment.

FIG. 19 is a cross-sectional view of a part of a process of manufacturing an organic EL display device in accordance with an embodiment.

FIG. 20 is a cross-sectional view of a part of a process of manufacturing an organic EL display device in accordance with an embodiment.

FIG. 21 is a cross-sectional view of a part of a process of manufacturing an organic EL display device in accordance with an embodiment.

FIG. 22 is a cross-sectional view of a part of a process of manufacturing an organic EL display device in accordance with an embodiment.

FIG. 23 is a cross-sectional view of a part of a process of manufacturing an organic EL display device in accordance with an embodiment.

FIG. 24 is a cross-sectional view of a part of a process of manufacturing an organic EL display device in accordance with an embodiment.

FIG. 25 is a cross-sectional view of a portion, of an organic EL display device in accordance with a first variation example, corresponding to FIG. 4.

FIG. 26 is a cross-sectional view of a portion, of the organic EL display device in accordance with the first variation example, corresponding to FIG. 14.

FIG. 27 is a cross-sectional view of a portion, of an organic EL display device in accordance with a second variation example, corresponding to FIG. 4.

FIG. 28 is a cross-sectional view of a portion, of the organic EL display device in accordance with the second variation example, corresponding to FIG. 14.

FIG. 29 is a cross-sectional view of a part of a process of manufacturing an organic EL display device in accordance with a comparative example.

FIG. 30 is a cross-sectional view of a part of a process of manufacturing an organic EL display device in accordance with a comparative example.

### DESCRIPTION OF EMBODIMENTS

The following will describe illustrative embodiments in detail with reference to drawings. The embodiments below will take an organic EL display device as an example of a display device in accordance with the present disclosure. Note that the drawings have been prepared to illustrate the concepts of the technique of the present disclosure. Therefore, the drawings may exaggerate or simplify dimensions, ratios, or numbers to facilitate the understanding of the technique of the present disclosure.

Throughout the following embodiments, the “first direction” refers to the horizontal direction on the display screen when the display device is used in the prescribed orientation. The “second direction” is perpendicular to the first direction and refers to the vertical direction on the display screen when the display device is used in the prescribed orientation. A row of structural members such as subpixels refers to a horizontal string of the structural members aligned in the first direction. A column of structural members such as subpixels refers to a vertical string of the structural members aligned in the second direction.

Throughout the following embodiments, a structural member such as a film, a layer, or an element may be described as being disposed, provided, or formed on another structural member such as a film, a layer, or an element not only when the former structural member sits directly on the latter structural member, but also when these structural members are separated by another, intervening structural member such as a film, a layer, or an element.

Throughout the following embodiments, a structural member may be described as being connected to another structural member when these structural members are electrically connected together unless otherwise mentioned explicitly. This language may be used not only when the structural members are directly connected, but also when the structural members are indirectly connected via yet another structural member, without departing from the scope of the technique of the present disclosure. The language may be used also when a structural member is integrated with another structural member, in other words, a structural member partially constitutes another structural member.

Throughout the following embodiments, a structural member may be described as being in the same layer as another structural member when these structural members are formed in the same process. A structural member may be described as underlying/being below another structural member when the former structural member is either formed in an earlier process or step than is the latter structural member or made out of a film formed in an earlier process or step than is the latter structural member. A structural member may be described as overlying/being on/being above another structural member when the former structural member is either formed in a later process or step than is the latter structural member or made out of a film formed in a later process or step than is the latter structural member.

Throughout the following embodiments, a structural member may be described as being identical or equivalent to another structural member not only when these structural members are completely identical or completely equivalent, but also when the structural members are substantially identical or substantially equivalent where they may vary within the range of manufacturing variations and tolerances.

Throughout the following embodiments, the ordinal numbers, “first,” “second,” “third,” and the like, are used to distinguish between the structural members to which these numbers are assigned and do not limit their number or establish any order between them.

### Embodiments

An organic EL display device 1 in accordance with this embodiment is used in a display device of mobile apparatus such as a multifunctional telephone called a smartphone and a tablet terminal. The organic EL display device 1 may be used in a display device including personal computers (PCs), television units, and various other apparatus.

### Configuration of Organic EL Display Device

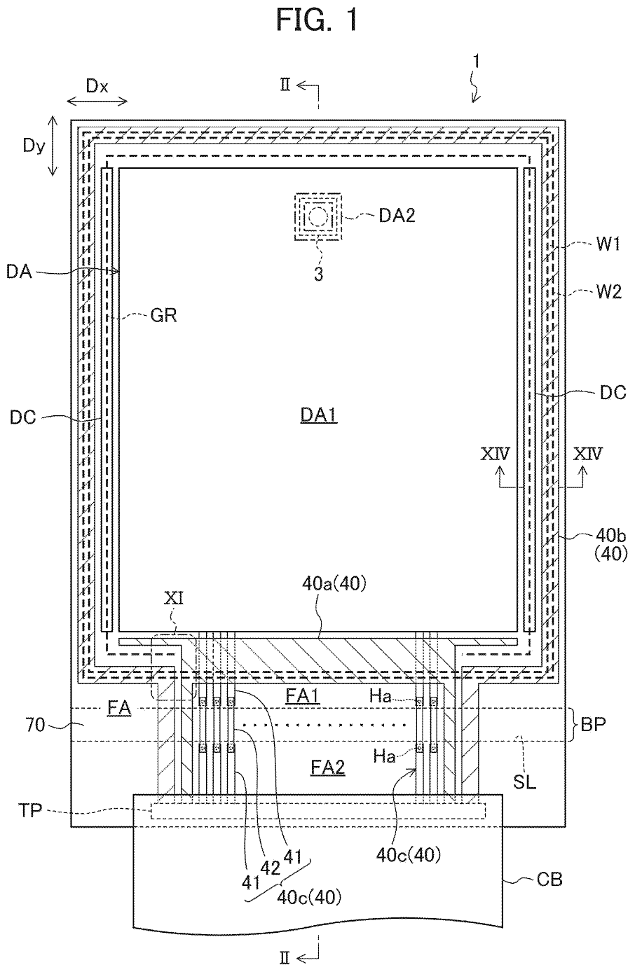

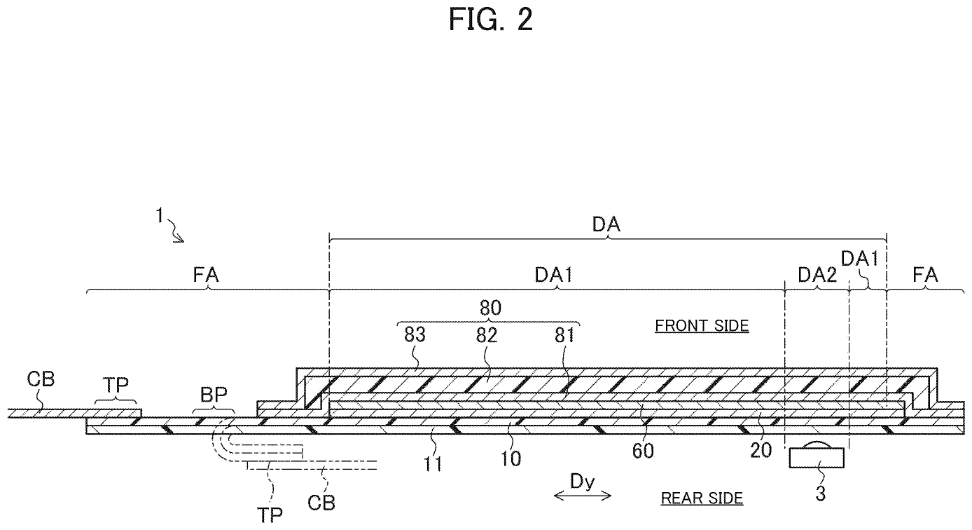

Referring to FIGS. 1 and 2, the organic EL display device 1 is combined with a camera 3, thereby at least partially constituting a display device equipped with an in-camera capable of capturing an image on the front side of the display screen by the camera 3. The organic EL display device 1 operates by active matrix drive and is configured to produce full-color displays. The organic EL display device 1 has a display area DA and a frame area FA.

The display area DA is an area for producing image displays and provides a display screen. The display area DA is formed to be, for example, rectangular. The display area DA may have a generally rectangular shape including a shape with at least one curved side, a shape with at least one round corner, and a shape with at least one notched side and may even have any other shape.

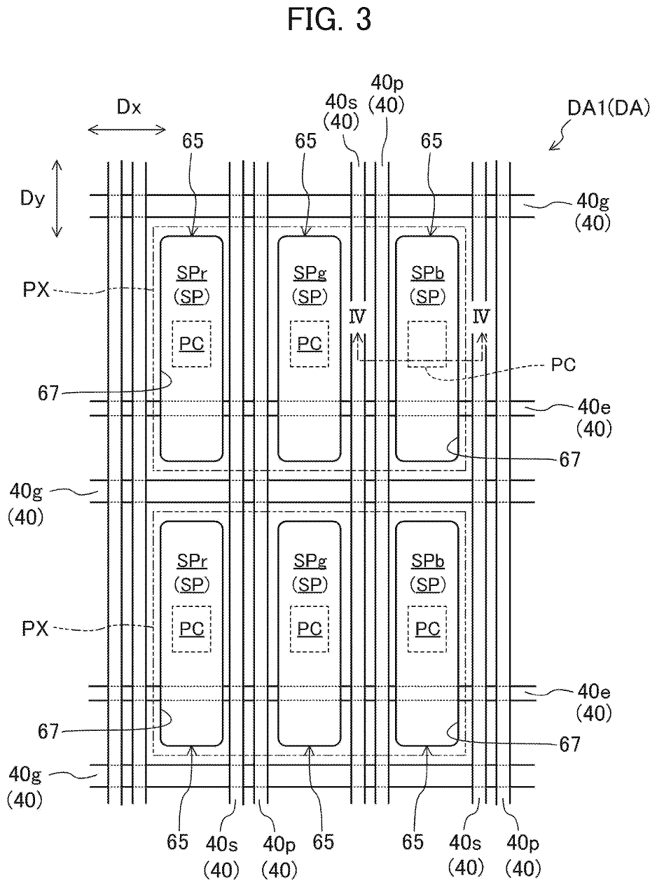

Referring to FIG. 3, the display area DA is provided by a plurality of pixels PX. The plurality of pixels PX are arranged in a matrix. Each pixel PX is provided by three subpixels SP. The three subpixels SP are a red light-emitting subpixel SPr, a green light-emitting subpixel SPg, and a blue light-emitting subpixel SPb. These three subpixels SPr, SPg, and SPb are arranged, for example, in stripes.

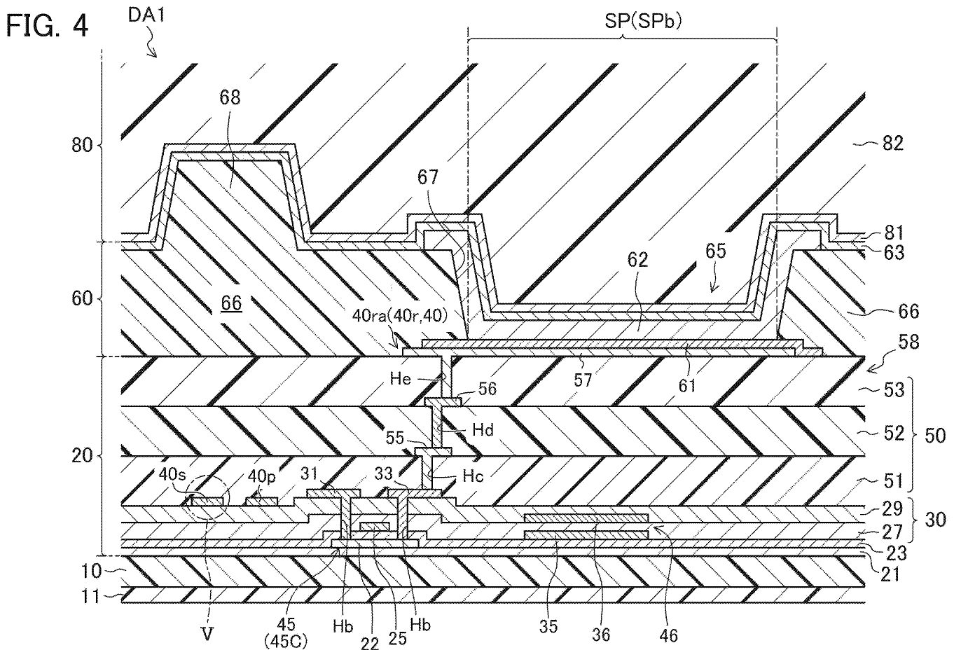

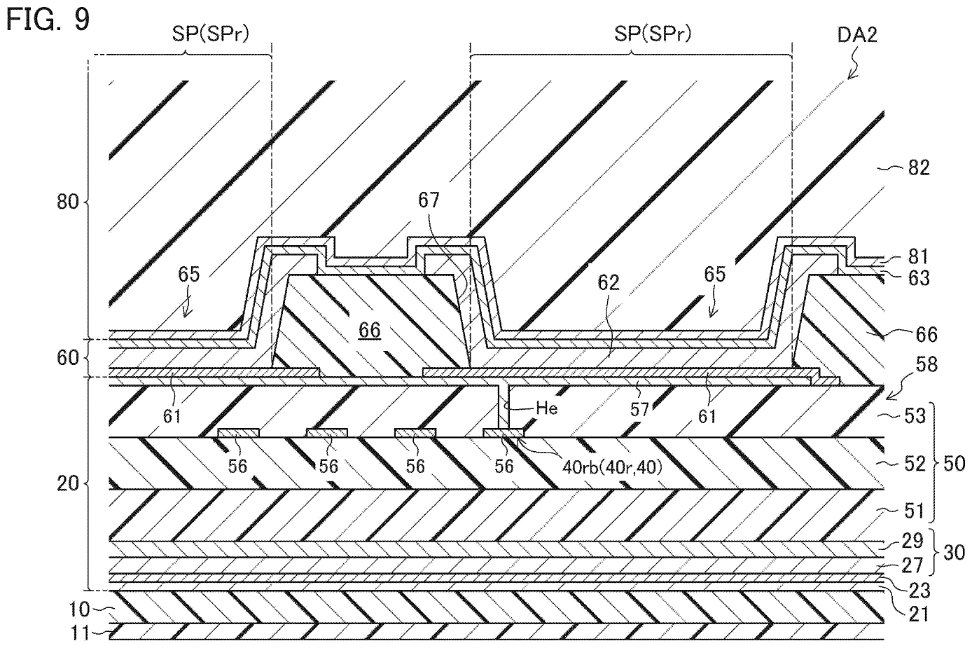

The display area DA includes a plurality of organic EL elements 65 and a plurality of pixel circuits PC. The plurality of organic EL elements 65 are provided correspondingly to the plurality of subpixels SP. Each subpixel SP includes one of the organic EL elements 65. One of the pixel circuits PC is provided basically for each subpixel to control the emission of light by the organic EL element 65. The organic EL element 65 and the pixel circuit PC that are provided correspondingly to each other are connected together by one of connection wires 40r which will be described later in detail (see FIGS. 4 and 9).

Referring to FIGS. 1 and 2, the camera 3 is disposed in such a position on the rear side of a substrate layer 10 that is a part of the organic EL display device 1 as to overlap the display area DA in a plan view. The camera 3 is an example of electronic components that utilize light. The camera 3 includes a CCD (charge coupled device), a CMOS (complementary metal oxide semiconductor) sensor, or a like image sensor. The camera 3 is disposed inside a housing (not shown) that contains the organic EL display device 1.

The display area DA has a first display area DA1 and a second display area DA2. The first display area DA1 occupies most of the display area DA. The second display area DA2 is provided internal to the first display area DA1. The second display area DA2 transmits light used by the camera 3. The second display area DA2 is provided, for example, near an end of the display area DA (toward the top in FIG. 1) and has a rectangular shape. The second display area DA2 may have a circular, elliptical, or any other shape.

The frame area FA is a part of a non-display section that is not the display screen. The frame area FA is provided around the display area and shaped like, for example, a rectangular frame. The frame area FA may be shaped like a non-rectangular frame. The frame area FA includes a terminal section TP and a bending portion BP. The terminal section TP is a portion for connecting to external circuits such as a display control circuit (source driver). The terminal section TP is provided in a position toward an outer edge of a portion of a side of the frame area FA in a first direction Dx so as to extend along this side.

The bending portion BP is provided in the frame area FA between the terminal section TP and the display area DA. The bending portion BP is bent around a bending axis extending in the first direction Dx. The bending portion BP extends horizontally so as to span all across the frame area FA in the first direction Dx. In the bending portion BP, a TFT layer 20 (detailed later) has a slit SL (not shown in FIG. 2) formed therein.

The slit SL is formed like a groove that extends across the bending portion BP in the direction in which the bending portion BP extends so as to run through the stack body of inorganic insulation films (specifically, a basecoat film 21, a gate insulation film 23, and an interlayer insulation film 30) in the TFT layer 20 and as to expose the substrate layer 10. The slit SL contains an injection layer 70 therein. The slit SL is filled in by the injection layer 70. This structure imparts more flexibility to the bending portion BP than to other members.

The frame area FA of the organic EL display device 1 is bent, for example, approximately 180° so that the bending portion BP forms a U-shape (indicated by dash-double-dot lines in FIG. 2). This bending places the terminal section TP on the rear side of the organic EL display device 1. The terminal section TP has a plurality of terminals (not shown). A wiring board CB such as an FPC (flexible printed circuit) is connected to the terminal section TP.

In addition, a drive circuit DC is provided in the frame area FA. The drive circuit DC is disposed in portions of the frame area FA that provide sides that are adjacent to the side on which the terminal section TP is disposed (the left and right sides in FIG. 1). The drive circuit DC is formed monolithically as a part of the TFT layer 20 which will be described later in detail. The drive circuit DC includes a gate driver and an emission driver.

A trench GR is provided in a planarization film 50 (detailed later) in the frame area FA. The trench GR is formed generally like the letter C that is open toward the terminal section TP in a plan view so as to surround the display area DA. The trench GR runs through the planarization film 50 and divides the planarization film 50 so as to separate the planarization film 50 between inside the frame area FA and outside the frame area FA (see FIG. 13). The trench GR plays a role of preventing moisture and water from penetrating from outside the frame area FA into the display area DA.

In the frame area FA are there further provided: a first frame line 40a (shown by left-rising hatching in FIG. 1 for convenience); a second frame line 40b (shown by right-rising hatching in FIG. 1 for convenience); a first damming wall W1; a second damming wall W2; and a plurality of draw-out lines 40c. Each of the first damming wall W1 and the second damming wall W2 is an example of a wall body. The first frame line 40a is an example of a first wiring line. The second frame line 40b is an example of a second wiring line.

The first frame line 40a and the second frame line 40b are power trunk lines for applying voltages (ELVDD, ELVSS) to the organic EL elements 65.

The first frame line 40a is provided so as to extend broadly in the first direction Dx in a portion where the trench GR is open. Both ends of the first frame line 40a on the display area DA side extend on the display area DA side of the trench GR. Both ends of the first frame line 40a on the terminal section TP side extend to the terminal section TP. The first frame line 40a is fed with a high-level power supply voltage (ELVDD) in the terminal section TP via the wiring board CB.

The second frame line 40b is provided generally like the letter C outside the trench GR so as to surround the display area DA. Both ends of the second frame line 40b extend along the first frame line 40a to the terminal section TP. The second frame line 40b is fed with a low-level power supply voltage (ELVSS) in the terminal section TP via the wiring board CB.

The first damming wall W1 and the second damming wall W2 are provided like a frame extending along the outer circumference of the trench GR so as to surround the display area DA. The second damming wall W2 is positioned along the outer circumference of the first damming wall W1 and formed at a distance from the first damming wall W1 in the width direction of the frame area FA. The first damming wall W1 and the second damming wall W2 play a role of damming up a liquid material (organic resin material) for an organic layer 82 (detailed later) from spreading outside the frame area FA when the liquid material is applied in the manufacture of the organic EL display device 1.

The plurality of draw-out lines 40c are drawn out from the display area DA to the terminal section TP. Each draw-out line 40c extends so as to run below the first frame line 40a, the first damming wall W1, and the second damming wall W2. Each draw-out line 40c is connected to one of source lines 40s (detailed later) on the display area DA side. Each draw-out line 40c includes a pair of underlying draw-out lines 41 and an overlying draw-out line 42.

The pair of underlying draw-out lines 41 are provided so as to be divided between a first portion FA1 that resides between the display area DA and the bending portion BP and a second portion FA2 that resides between the bending portion BP and the terminal section TP. The plurality of underlying draw-out lines 41 in the first portion FA1 and the plurality of underlying draw-out lines 41 in the second portion FA2 are disposed at a distance from each other in the first direction Dx and extend parallel to each other in a second direction Dy.

The plurality of overlying draw-out lines 42 extend parallel to each other in the second direction Dy on the injection layer 70 so as to run over the bending portion BP and are provided at a distance from each other in the first direction Dx. Each overlying draw-out line 42 is connected, via a first contact hole Ha formed in the interlayer insulation film 30 (detailed later), to the pair of underlying draw-out lines 41 positioned on both sides of the bending portion BP in the second direction Dy.

### Layered Structure of Organic EL Display Device

Referring to FIG. 2, the organic EL display device 1 includes the substrate layer 10, the TFT layer (thin film transistor layer) 20, a light-emitting element layer 60, and a sealing film 80. The substrate layer 10 and the TFT layer 20 form a circuit board called a back plane.

### Substrate Layer

The substrate layer 10 is a layer that provides a base for the organic EL display device 1. The substrate layer 10 is an example of a substrate. The substrate layer 10 is flexible. The substrate layer 10 is made of an organic resin material such as a polyimide resin, a polyamide resin, or an epoxy resin. A protective film 11 that is transparent to light (“transparent to light” in the present example means “transparent to visible light” throughout this example) is attached to the rear face of the substrate layer 10.

### TFT Layer

The TFT layer 20 is provided on the substrate layer 10. The TFT layer 20 includes various wires 40 and the plurality of pixel circuits PC shown in FIG. 3 as well as the above-described drive circuit DC. The drive circuit DC, the various wires 40, and the pixel circuits PC are provided on the basecoat film 21 shown in FIG. 4. The basecoat film 21 is provided generally across the surface of the substrate layer 10.

The various wires 40 include the first frame line 40a, the second frame line 40b, and the plurality of draw-out lines 40c, all described earlier, and further include a plurality of gate lines 40g, a plurality of light-emission control lines 40e, a plurality of power supply lines 40p, and the plurality of source lines 40s. In addition, the various wires 40 further include the plurality of connection wires 40r. The plurality of connection wires 40r will be described later in detail.

The plurality of gate lines 40g, the plurality of light-emission control lines 40e, the plurality of power supply lines 40p, the plurality of source lines 40s, and the plurality of connection wires 40r are all provided in the display area DA.

The plurality of gate lines 40g are wires for transferring a gate signal to the pixel circuits PC. The plurality of gate lines 40g are disposed at a distance from each other in the second direction Dy and extend parallel to each other in the first direction Dx. One of the gate lines 40g is provided for each row of subpixels SP. Each gate line 40g is drawn out to the frame area FA for connection to a gate driver in the drive circuit DC.

The plurality of light-emission control lines 40e are wires for transferring an emission signal to the pixel circuits PC. The plurality of light-emission control lines 40e are disposed at a distance from each other in the second direction Dy and extend parallel to each other in the first direction Dx. One of the light-emission control lines 40e is provided for each row of subpixels SP. Each light-emission control line 40e is drawn out to the frame area FA for connection to an emission driver in the drive circuit DC.

The plurality of power supply lines 40p are wires for applying a prescribed high-level power supply voltage (ELVDD) to the pixel circuits PC. The plurality of power supply lines 40p are disposed at a distance from each other in the first direction Dx and extend parallel to each other in the second direction Dy. One of the power supply lines 40p is provided for each column of subpixels SP. Each power supply line 40p is drawn out to the frame area FA on the terminal section TP side for connection to the first frame line 40a.

The plurality of source lines 40s are wires for transferring a source signal to the pixel circuits PC. The plurality of source lines 40s are disposed at a distance from each other in the first direction Dx and extend parallel to each other in the second direction Dy. One of the source lines 40s is provided for each column of subpixels SP. Each source line 40s is connected to one of the draw-out lines 40c and is connected also to a display control circuit (source driver) via the wiring board CB.

The gate lines 40g, the light-emission control lines 40e, and the underlying draw-out lines 41 are made of the same material, and provided in the same layer, as gate electrodes 25 and first capacitor electrodes 35 (detailed later). The power supply lines 40p and the source lines 40s are made of the same material, and provided in the same layer, as first terminal electrodes 31 and second terminal electrodes 33 (detailed later). The overlying draw-out lines 42 are made of the same material, and provided in the same layer, as underlying partial wires 55 (detailed later).

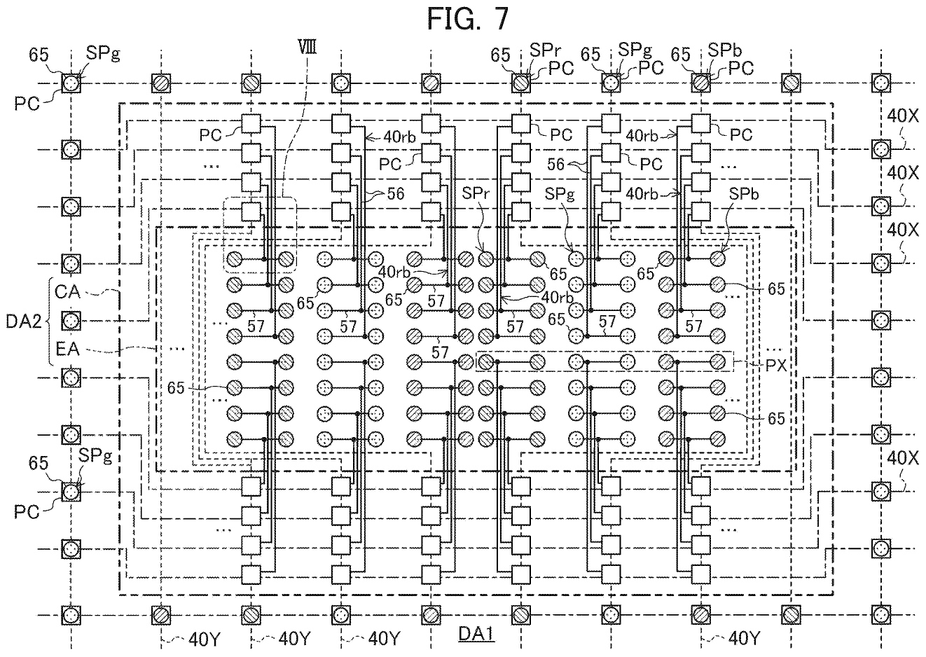

One of the pixel circuits PC is provided for each subpixel SP (organic EL element 65) in the first display area DA1 (see FIG. 3) and for each two subpixels SP (organic EL elements 65) that collaborate in light emission control in the second display area DA2 (see FIG. 7). The gate lines 40g, the light-emission control lines 40e, and the power supply lines 40p are connected to the pixel circuits PC.

The pixel circuit PC includes a plurality of TFTs 45 and a capacitor 46. Referring to FIG. 4, the plurality of TFTs 45 have a top gate structure. Each TFT 45 includes a semiconductor layer 22, the gate insulation film 23, the gate electrode 25, the interlayer insulation film 30, the first terminal electrode 31, and the second terminal electrode 33.

The semiconductor layer 22 is provided insularly on the basecoat film 21. The semiconductor layer 22 is separated individually for each TFT 45. The semiconductor layer 22 may be provided contiguously for the plurality of TFTs 45. The semiconductor layer 22 has a channel region and a pair of conductive regions. The channel region is provided between the pair of conductive regions. The pair of conductive regions are provided at a distance from each other across the channel region.

The semiconductor layer 22 is made of, for example, a low-temperature polycrystalline silicon (LTPS). The semiconductor layer 22 may be made of an oxide semiconductor. The oxide semiconductor may be, for example, an indium gallium zinc oxide (In—Ga—Zn—O)-based semiconductor.

The gate insulation film 23 is provided so as to cover the plurality of semiconductor layers 22. The gate insulation film 23 may be provided insularly so as to overlap each semiconductor layer 22 and separated individually for each TFT 45. The gate electrode 25 is provided on the gate insulation film 23. The gate electrode 25 overlaps the channel region of the semiconductor layer 22 via the gate insulation film 23.

The interlayer insulation film 30 includes a first interlayer insulation film 27 and a second interlayer insulation film 29 that are stacked in this order on the gate insulation film 23. The interlayer insulation film 30 is provided so as to cover the plurality of gate electrodes 25. In the gate insulation film 23 and the interlayer insulation film 30, a pair of second contact holes Hb are formed for each TFT 45. The pair of second contact holes Hb run through mutually different conductive regions of the semiconductor layer 22.

The first terminal electrode 31 and the second terminal electrode 33 are provided at a distance from each other on the second interlayer insulation film 29. The first terminal electrode 31 and the second terminal electrode 33 are connected to the semiconductor layer 22 via the mutually different contact holes Hb. In the semiconductor layer 22, the first terminal electrode 31 is connected to one of the conductive regions, and the second terminal electrode 33 is connected to the other one of the conductive regions.

The capacitor 46 includes the first capacitor electrode 35, a second capacitor electrode 36, and the first interlayer insulation film 27. The first capacitor electrode 35 is provided on the gate insulation film 23. The second capacitor electrode 36 is provided on the first interlayer insulation film 27. The first capacitor electrode 35 and the second capacitor electrode 36 overlap each other via the first interlayer insulation film 27.

The basecoat film 21, the gate insulation film 23, the first interlayer insulation film 27, and the second interlayer insulation film 29 are made of an inorganic insulating material such as silicon oxide, silicon nitride, or silicon oxynitride. Each of these basecoat film 21, gate insulation film 23, first interlayer insulation film 27, and second interlayer insulation film 29 may include either a monolayer film or a multilayer film.

The above-described various wires and electrodes are made of, for example, a metal material such as aluminum (Al), tungsten (W), molybdenum (Mo), tantalum (Ta), chromium (Cr), titanium (Ti), or copper (Cu). These various wires and electrodes may include either a monolayer film or a multilayer film.

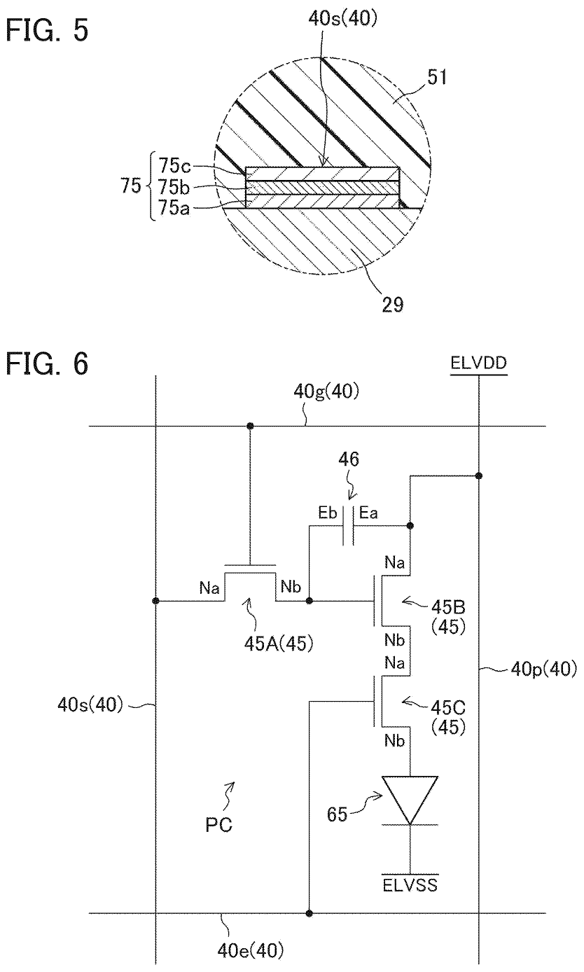

For instance, the source line 40s, the overlying draw-out line 42, the first terminal electrode 31, and the second terminal electrode 33 are made out of a first multilayer film 75 shown in FIG. 5. The first multilayer film 75 includes a stack of a first metal layer 75a, a second metal layer 75b, and a third metal layer 75c. The first metal layer 75a is formed on the surface of the second interlayer insulation film 29. The second metal layer 75b and the third metal layer 75c are stacked in this order on the first metal layer 75a.

The first metal layer 75a and the third metal layer 75c are made of, for example, a metal such as titanium (Ti), molybdenum (Mo), chromium (Cr), or tantalum (Ta). The first metal layer 75a and the third metal layer 75c may be made of, for example, a metal compound or an alloy. The second metal layer 75b is made of, for example, a metal such as aluminum (Al), silver (Ag), or gold (Au). The second metal layer 75b may be made of a metal compound or an alloy.

As a more specific example, the first multilayer film 75 may include a stack of a titanium layer (Ti layer) as the first metal layer 75a, an aluminum layer (Al layer) as the second metal layer 75b, and a titanium layer (Ti layer) as the third metal layer 75c. The first multilayer film 75 may include a titanium alloy layer (Ti alloy layer) in place of the titanium layer (Ti layer). In addition, the first multilayer film 75 may include an aluminum alloy layer (Al alloy layer) in place of the aluminum layer (Al layer). This first multilayer film 75 is preferred in constructing, for example, low-resistance wires and electrodes.

The TFT layer 20 further includes the planarization film 50 and the plurality of connection wires 40r. The planarization film 50 in accordance with the present example includes a stack of a first planarization film 51, a second planarization film 52, and a third planarization film 53. The first planarization film 51, the second planarization film 52, and the third planarization film 53 are all examples of a first organic insulation film.

The first planarization film 51 is provided on the second interlayer insulation film 29 so as to cover the plurality of TFTs 45 and the plurality of capacitors 46. The second planarization film 52 and the third planarization film 53 are stacked in this order on the first planarization film 51. The first planarization film 51, the second planarization film 52, and the third planarization film 53 spread across the entire display area DA.

Each of the first planarization film 51, the second planarization film 52, and the third planarization film 53 is made of an organic insulating material and transparent to light. This organic insulating material may be a photosensitive resin. The photosensitive resin may be, for example, an organic resin material such as a polyimide resin or an acrylic resin or a polysiloxane-based SOG (spin on glass) material. The TFT layer 20 has a surface thereof planarized by the planarization film 50.

The plurality of connection wires 40r are provided in the display area DA. Each connection wire 40r connects one of the pixel circuits PC (strictly, a prescribed one of the TFTs 45 in the pixel circuits PC) and one of the organic EL elements 65 that corresponds to the one of the pixel circuits PC. One of the connection wires 40r is provided for each one of the pixel circuits PC. In the organic EL display device 1 in accordance with the present example, the connection wires 40r include a plurality of first connection wires 40ra and a plurality of second connection wires 40rb.

The plurality of first connection wires 40ra are those connection wires 40r which are positioned in the first display area DA1. The plurality of second connection wires 40rb are those connection wires 40r which are positioned in the second display area DA2. Each of the first connection wires 40ra and the second connection wires 40rb includes one of the underlying partial wires 55, an intermediate partial wire 56, and an overlying partial wire 57 (see FIGS. 4, 9, and 10). The underlying partial wire 55, the intermediate partial wire 56, and the overlying partial wire 57 are all examples of partial wires and provided in mutually different layers via an individual layer of the planarization film 50 (first organic insulation film).

The underlying partial wire 55 is an underlying one of the plurality of partial wires. The underlying partial wire 55 is provided insularly on the first planarization film 51 and positioned underlying the second planarization film 52. The first planarization film 51 has a third contact hole Hc formed therein for each of the pixel circuits PC. The third contact hole Hc runs through to either the second terminal electrode 33 of a prescribed one of the TFTs 45 (third TFT 45C) or a wire connected to this second terminal electrode 33. The underlying partial wire 55 is connected to a prescribed, corresponding one of the TFTs 45 (third TFT 45C) via the third contact hole Hc.

The intermediate partial wire 56 is an intermediate one of the plurality of partial wires. The intermediate partial wire 56 is provided insularly on the second planarization film 52 and positioned underlying the third planarization film 53. The second planarization film 52 has a fourth contact hole Hd formed therein for each of the pixel circuits PC. The fourth contact hole Hd runs through to the underlying partial wire 55. The intermediate partial wire 56 is connected to a corresponding one of the underlying partial wires 55 via the fourth contact hole Hd.

The overlying partial wire 57 is an overlying one of the plurality of partial wires. The overlying partial wire 57 is provided insularly on the third planarization film 53 and positioned underlying a first electrode 61 in the organic EL element 65. The third planarization film 53 has a fifth contact hole He formed therein for each of the pixel circuits PC. The fifth contact hole He runs through to the intermediate partial wire 56. The overlying partial wire 57 is connected to a corresponding one of the intermediate partial wires 56 via the fifth contact hole He.

As described here, the first planarization film 51, the underlying partial wire 55, the second planarization film 52, the intermediate partial wire 56, the third planarization film 53, and the overlying partial wire 57 are stacked in this order to provide a multilayered structural portion 58. The multilayered structural portion 58 has a structure in which a partial wire that provides the connection wire 40r and an organic insulation film (first organic insulation film) are alternately stacked. The multilayered structural portion 58 in accordance with the present example has a three-layered insulation structure including three layers of organic insulation films.

The underlying partial wire 55 is, similarly to the first frame line 40a and the second frame line 40b, made out of a second multilayer film 76 (detailed later). The intermediate partial wire 56 and the overlying partial wire 57 are both made of a conductive, transparent material that is transparent to light. This conductive, transparent material may be, for example, indium tin oxide (ITO). Each of the intermediate partial wire 56 and the overlying partial wire 57 may include either a monolayer film or a multilayer film.

### Light-Emitting Element Layer

The light-emitting element layer 60 is provided on the TFT layer 20. Referring to FIG. 4, the light-emitting element layer 60 includes the plurality of organic EL elements (organic electroluminescence elements) 65 and an edge cover 66. The organic EL element 65 is an example of a light-emitting element. The edge cover 66 is an example of a second organic insulation film. The organic EL element 65 has a top-emission structure. The organic EL element 65 emits light that is retrieved on the sealing film 80 side.

The plurality of organic EL elements 65 are provided correspondingly to the plurality of subpixels SP. Each individual organic EL element 65 provides one of the subpixels SP. The emission of light by each organic EL element 65 is controlled by the operation of the corresponding one of the pixel circuits PC. Each organic EL element 65 includes the first electrode 61, an organic EL layer 62, and a second electrode 63. The organic EL layer 62 is an example of an electroluminescence layer.

The first electrodes 61 are separated individually and provided on the third planarization film 53, in other words, on the multilayered structural portion 58. The first electrodes 61 are arranged in a matrix correspondingly to the plurality of subpixels SP. Each first electrode 61 is connected to a prescribed one of the TFTs 45 (third TFT 45C) via one of the connection wires 40r. The first electrode 61 serves as an anode and injects holes to the organic EL layer. The first electrode 61 is preferably made of a conductive material that exhibits a high work function.

The first electrode 61 is made of, for example, a metal such as silver (Ag), aluminum (Al), nickel (Ni), titanium (Ti), indium (In), or tin (Sn). The first electrode 61 may be made of, for example, a metal compound or an alloy. The first electrode 61 may be made of a conductive oxide such as indium tin oxide (ITO) or indium zinc oxide (IZO). The first electrode 61 may include either a monolayer film or a multilayer film.

As a more specific example, the first electrode 61 may include an indium tin oxide layer (ITO layer), a silver alloy layer (Ag alloy layer), and another indium tin oxide layer (ITO layer) that are stacked in this order. The first electrode 61 may include a silver layer (Ag layer) in place of the silver alloy layer (Ag alloy layer). In addition, the first electrode 61 may include an aluminum layer (Al layer) and an indium zinc oxide layer (IZO layer) that are stacked in this order.

The edge cover 66 is provided on the third planarization film 53, in other words, on the multilayered structural portion 58 in the display area DA. The edge cover 66 is formed like a lattice so as to partition the plurality of first electrodes 61. The edge cover 66 is positioned in an overlying layer of the first electrode 61 and provided so as to extend between the first electrodes 61 that are adjacent to each other and as to cover the outer edges (peripheral portions) of the first electrodes 61.

The edge cover 66 has a plurality of openings 67 corresponding to the subpixels SP. Each opening 67 exposes one of the first electrodes 61 partially from the edge cover 66. The edge cover 66 is made of an organic resin material (photosensitive resin), similarly to the first planarization film 51, the second planarization film 52, or the third planarization film 53, such as an organic resin material including a polyimide resin and an acrylic resin or a polysiloxane-based SOG material.

The edge cover 66 has a surface thereof partially protruding toward the sealing film 80 to form a plurality of photospacers 68. The photospacers 68 are protrusions that play a role of maintaining, in the manufacture of the organic EL display device 1, a distance between a film-formation mask used to form a functional layer (e.g., light-emitting layer) in the organic EL layer 62 and the surface of a member on which a film is formed. Some of the photospacers 68 are provided in a prescribed pattern in both the first display area DA1 and the second display area DA2, and some of the photospacers 68 are provided also in the frame area FA.

The organic EL layer 62 is provided on the individual first electrodes 61 in the openings 67 in the edge cover 66. The organic EL layer 62 includes a hole injection layer, a hole transport layer, a light-emitting layer, an electron transport layer, and an electron injection layer. These hole injection layer, hole transport layer, light-emitting layer, electron transport layer, and electron injection layer are stacked in this order on the first electrodes 61 and are respectively made of publicly known compounds that are suited to their functions. The organic EL layer 62 emits light when an electric current is applied between the first electrode 61 and the second electrode 63.

The second electrode 63 is provided as a common film that is contiguous all across the plurality of subpixels SP, so as to spread across the entire display area DA. The second electrode 63 covers the edge cover 66 and each organic EL layer 62 and overlaps each first electrode 61 via the organic EL layer 62. The second electrode 63 spreads further into the frame area FA and is connected to the second frame line 40b in a region where the first damming wall W1 and the second damming wall W2 are provided. The second electrode 63 functions as a cathode and injects electrons to the organic EL layer 62. The second electrode 63 is preferably made of a conductive material that exhibits a low work function.

The second electrode 63 is made of, for example, a conductive oxide such as indium tin oxide (ITO) or indium zinc oxide (IZO). The second electrode 63 may be made of a metal such as silver (Ag), aluminum (Al), lithium (Li), magnesium (Mg), calcium (Ca), or ytterbium (Yb). The second electrode 63 may be made of, for example, a metal compound or an alloy. The second electrode may include either a monolayer film or a multilayer film.

### Sealing Film

The sealing film 80 is provided on the light-emitting element layer 60. Referring to FIG. 4, the sealing film 80 covers and thereby seals the plurality of organic EL elements 65 to protect the organic EL elements 65 (particularly, the organic EL layer 62) from, for example, moisture and oxygen. Referring to FIG. 2, the sealing film 80 is provided across the entire display area DA, spreading into the frame area FA. The sealing film 80 includes a first inorganic layer 81, the organic layer 82, and a second inorganic layer 83. The first inorganic layer 81, the organic layer 82, and the second inorganic layer 83 are provided in this order on the light-emitting element layer 60.

As shown further in FIGS. 12 to 14, the first inorganic layer 81 and the second inorganic layer 83 extend out of the organic layer 82 toward the outer circumference of the frame area FA, spread so as to cover the first damming wall W1 and the second damming wall W2, and overlap each other along the outer portion of the frame area FA. The organic layer 82 is provided internal to the first damming wall W1 and wrapped up by the first inorganic layer 81 and the second inorganic layer 83. The organic layer 82 may extend further to a region between the first damming wall W1 and the second damming wall W2.

Each of the first inorganic layer 81 and the second inorganic layer 83 is made of, for example, an inorganic insulating material such as silicon oxide, silicon nitride, or silicon oxynitride. The organic layer 82 is made of, for example, an organic resin material such as an acrylic resin, an epoxy resin, a silicone resin, a polyurea resin, a parylene resin, a polyimide resin, or a polyamide resin. The organic layer 82 is formed by applying a liquid material (organic insulating material).

### Pixel Circuit

The pixel circuit PC is configured like the equivalent circuit shown in FIG. 6. The plurality of TFTs 45 in the pixel circuit PC in accordance with the present example include a first TFT 45A, a second TFT 45B, and the third TFT 45C. In the equivalent circuit shown in FIG. 6, the first terminal electrode 31 of the TFT 45 is denoted by “Na,” the second terminal electrode 33 of the TFT 45 is denoted by “Nb,” the first capacitor electrode 35 of the capacitor 46 is denoted by “Ea,” and the second capacitor electrode 36 of the capacitor 46 is denoted by “Eb.”

The gate electrode 25 of the first TFT 45A is connected to a corresponding one of the gate lines 40g. The first terminal electrode 31 of the first TFT 45A is connected to a corresponding one of the source lines 40s. The second terminal electrode 33 of the first TFT 45A is connected to the gate electrode 25 of the corresponding second TFT 45B. The first terminal electrode 31 of the second TFT 45B is connected to a corresponding one of the power supply lines 40p. The second terminal electrode 33 of the second TFT 45B is connected to the first terminal electrode 31 of the corresponding third TFT 45C.

The gate electrode 25 of the third TFT 45C is connected to a corresponding one of the light-emission control lines 40e. The second terminal electrode 33 of the third TFT 45C is connected to the first electrode 61 of the corresponding organic EL element 65. The first capacitor electrode 35 of the capacitor 46 is connected to the power supply line 40p. The second capacitor electrode 36 of the capacitor 46 is connected to the second terminal electrode 33 of the first TFT 45A and to the gate electrode 25 of the second TFT 45B.

### Configuration of Organic EL Elements and Pixel Circuits

Referring to FIG. 7, in the second display area DA2, the positional relationship between the organic EL elements 65 and the pixel circuits PC differs than in the first display area DA1, and various wires extend in an irregular manner. FIG. 7 schematically shows, as an example, a positional relationship between the organic EL elements 65 and the pixel circuits PC in the second display area DA2 and in the first display area DA1 surrounding the second display area DA2.

The schematic illustration of FIG. 7 identifies each organic EL element 65 by a circular symbol graphic and each pixel circuit PC by a rectangular symbol graphic for convenience. Then, the schematic illustration of FIG. 7 shows the red light-emitting organic EL elements 65 by left-rising hatching, the green light-emitting organic EL elements 65 by dot hatching, and the blue light-emitting organic EL elements 65 by right-rising hatching.

In addition, in the schematic illustration of FIG. 7, the gate lines 40g and the light-emission control lines 40e are represented, for convenience, by a single wiring line (first metal wire 40X) that is shown by a dash-dot line. Each of the gate lines 40g and the light-emission control lines 40e extends with a shape similar to that of the first metal wire 40X. Furthermore, in the schematic illustration of FIG. 6 further, the source lines 40s and the power supply lines 40p are represented, for convenience, by a single wiring line (second metal wire 40Y) that is shown by a broken line. Each of the source lines 40s and the power supply lines 40p extends with a shape similar to that of the second metal wire 40Y.

In the first display area DA1, the pixel circuits PC are disposed in positions overlapping the corresponding organic EL elements 65 in a plan view and in their vicinity. This arrangement is shown in FIG. 7 by the overlapping graphics of the organic EL elements 65 and the pixel circuits PC. In other words, in the first display area DA1, each pixel circuit PC is disposed in a position overlapping the subpixel SP provided by the corresponding organic EL element 65.

Referring to FIG. 4, in the first display area DA1, the underlying partial wire 55, the intermediate partial wire 56, and the overlying partial wire 57 in each first connection wire 40ra are positioned in a region overlapping a corresponding one of the first electrodes 61 in a plan view or its surroundings. Hence, each first connection wire 40ra is locally drawn out from a prescribed one of the TFTs 45 onto the third planarization film 53. Each first electrode 61 in the first display area DA1 is provided overlapping the overlying partial wire 57 and is connected to the connection wire 40r.

Referring to FIG. 7, in the second display area DA2, the pixel circuits PC are disposed in separate positions not overlapping the corresponding organic EL elements 65 in a plan view. In the second display area DA2, the area where the organic EL elements 65 providing the subpixels SP are disposed and the area where the plurality of pixel circuits PC corresponding to these organic EL elements 65 are disposed are provided separately from each other. The second display area DA2 includes a light-emitting element area EA that is the former area and a circuit-arrangement area CA that is the latter area.

The light-emitting element area EA is provided in the center of the second display area DA2. The organic EL elements 65 are disposed in the light-emitting element area EA. Specifically, the light-emitting element area EA includes a plurality of sets of organic EL elements 65, with each set including two adjacent organic EL elements 65. The two organic EL elements 65 in each set are arranged side by side in the first direction Dx. These two organic EL elements 65 emit light of the same color.

The circuit-arrangement area CA is provided around the light-emitting element area EA. The circuit-arrangement area CA includes the plurality of pixel circuits PC. These pixel circuits PC are for controlling the emission of light by the organic EL elements 65 in the light-emitting element area EA. One of the pixel circuits PC in the circuit-arrangement area CA is provided for each set of organic EL elements 65 to commonly control the emission of light by this set of two organic EL elements 65.

In the second display area DA2, one of the second connection wires 40rb is provided for each combination of one of the sets of organic EL elements 65 and one of the pixel circuits PC. Each of these second connection wires 40rb connects the first electrodes 61 of the two organic EL elements 65 in a single corresponding set of organic EL elements 65 and one of the pixel circuits PC, or more strictly, a prescribed one of the TFTs 45 (third TFT 45C).

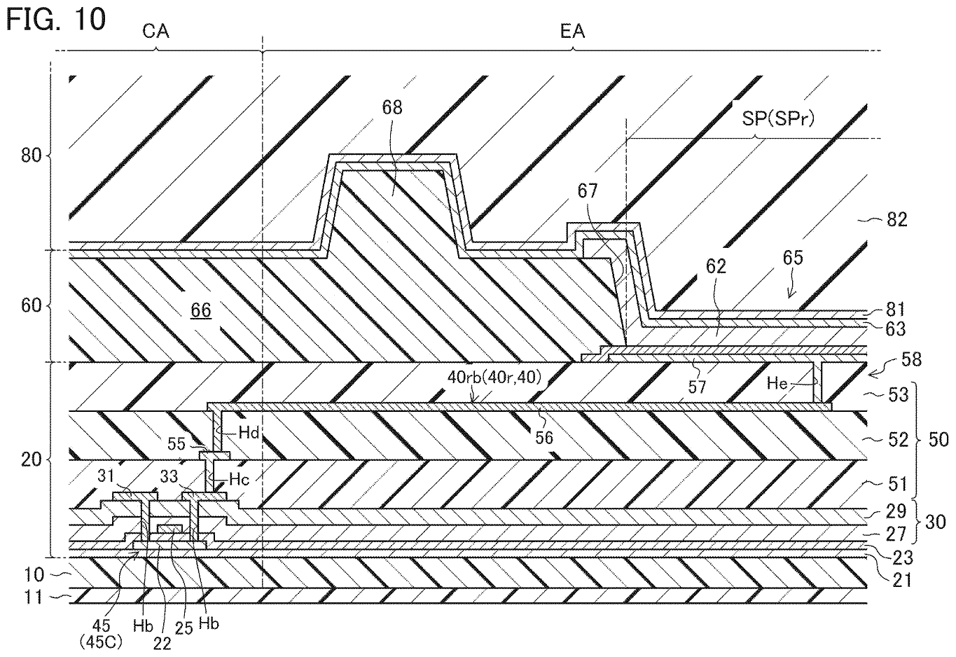

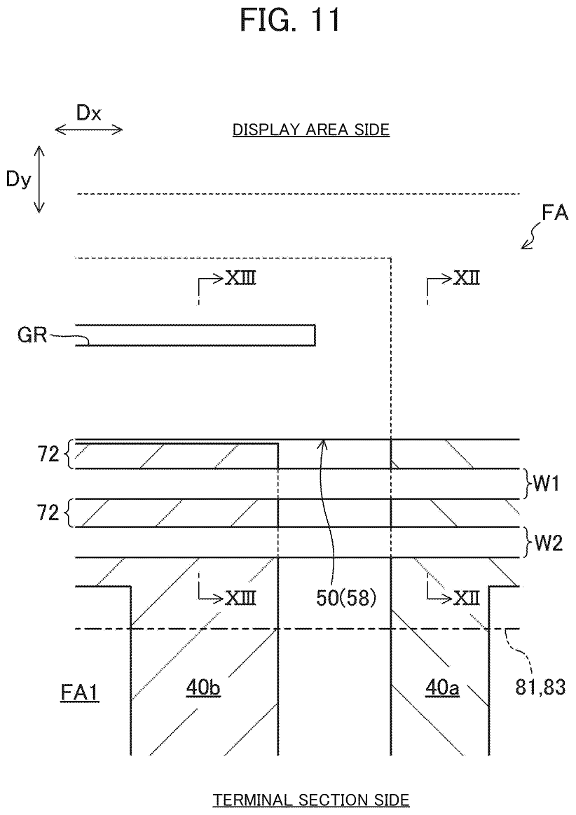

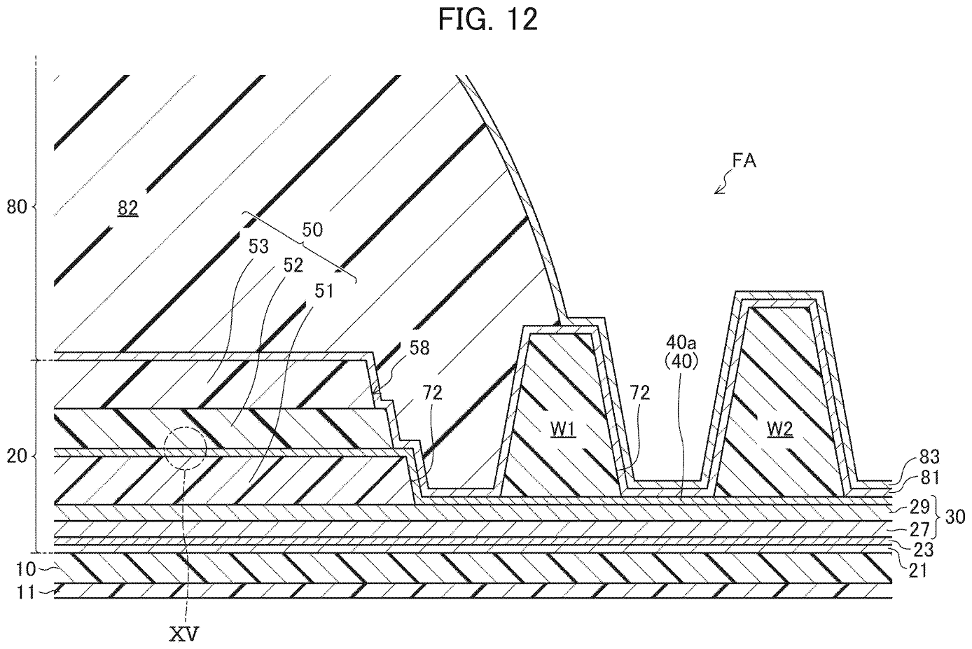

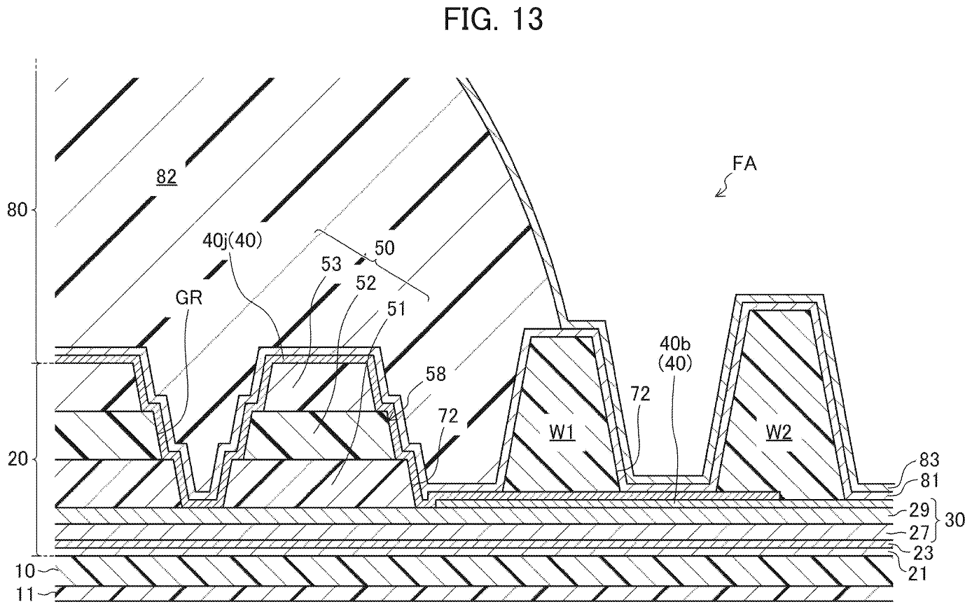

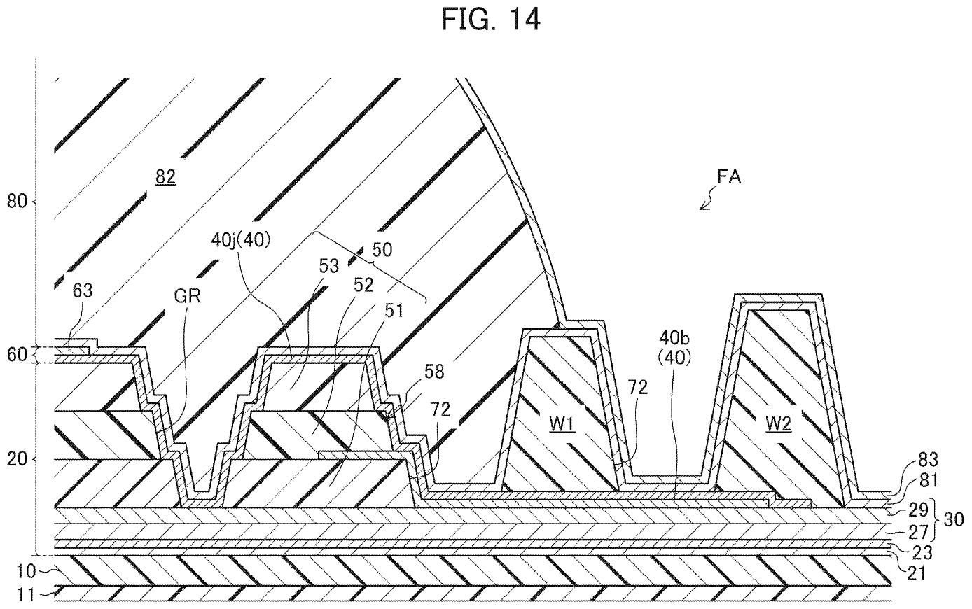

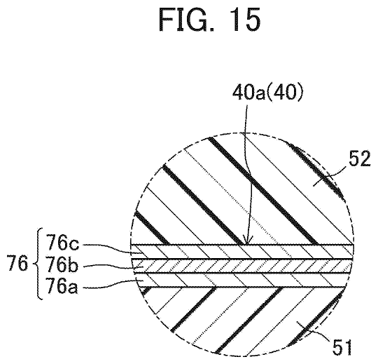

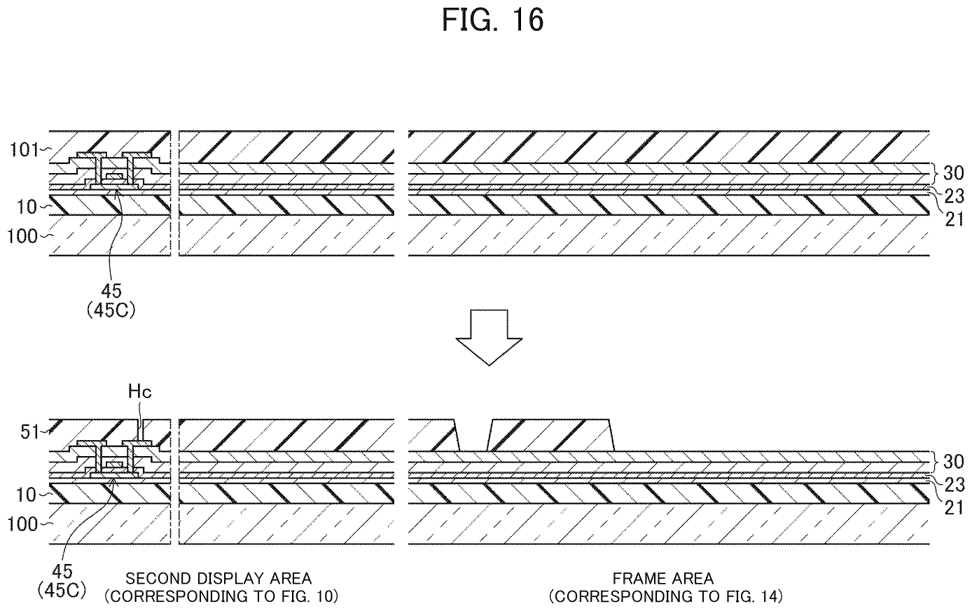

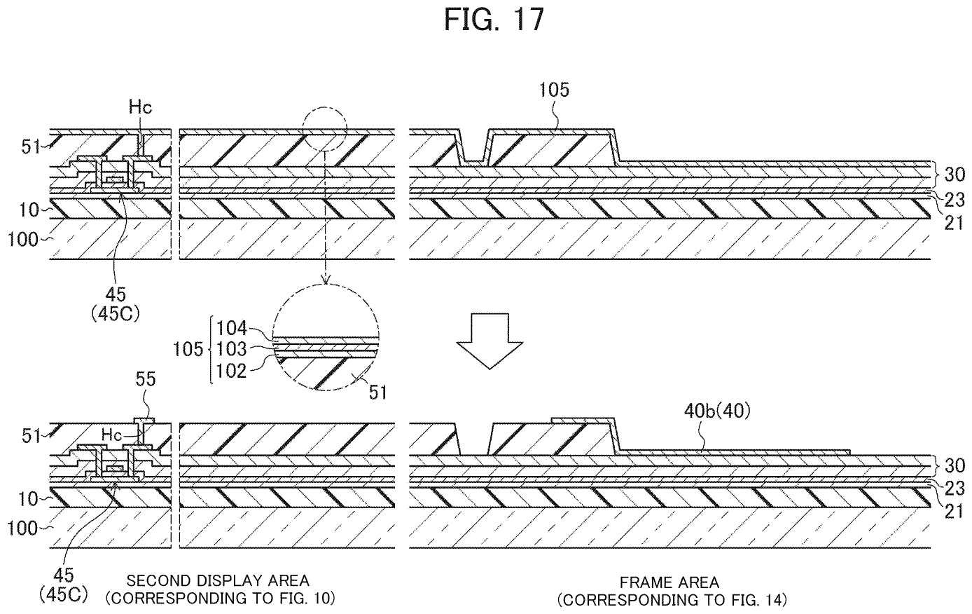

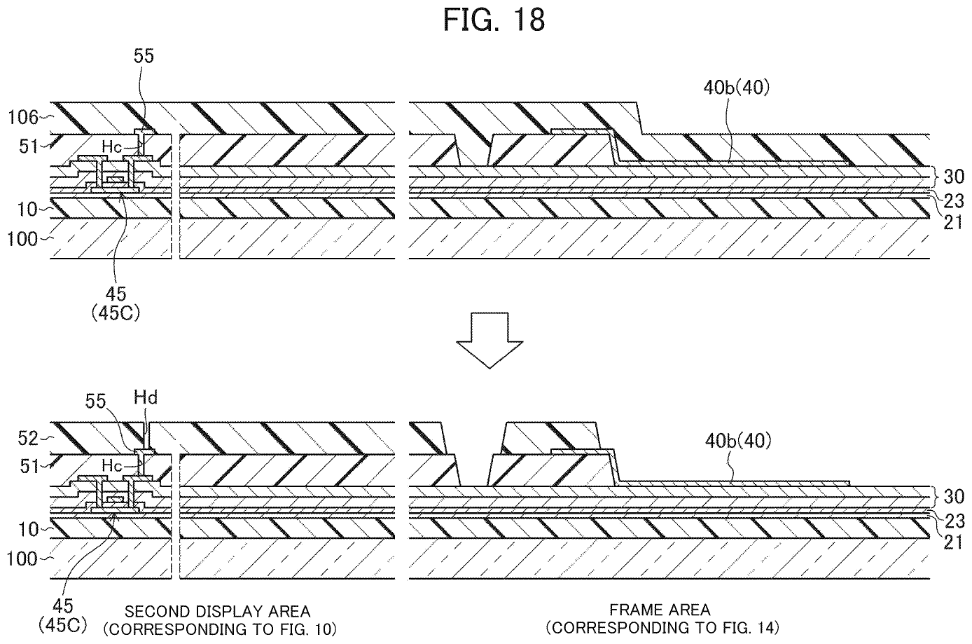

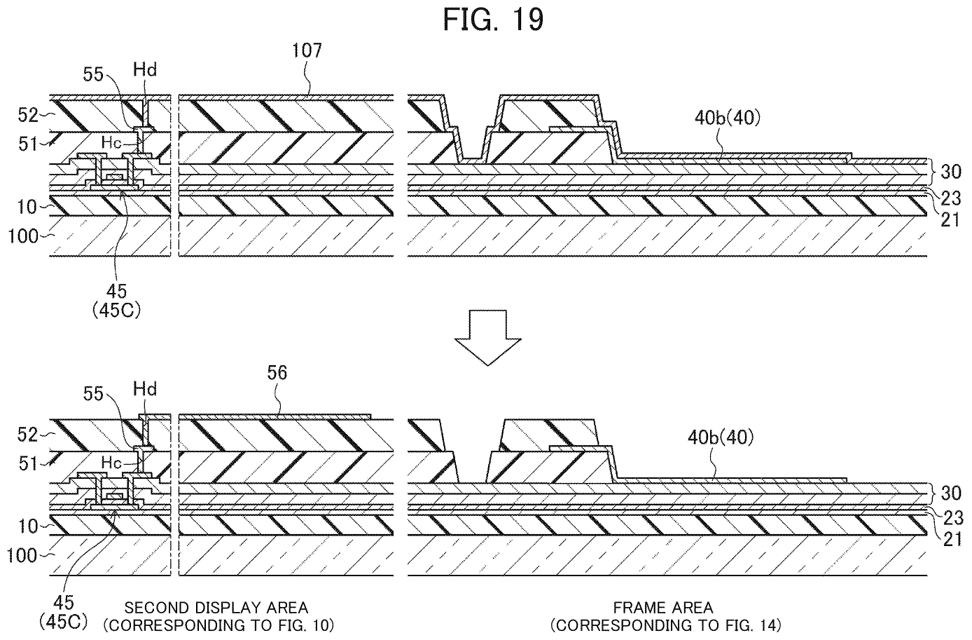

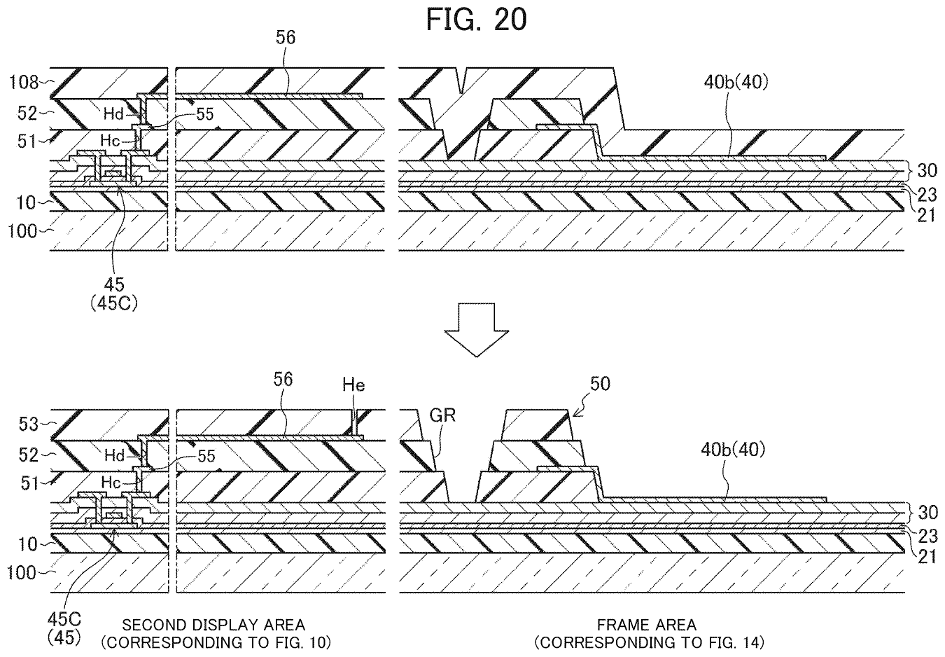

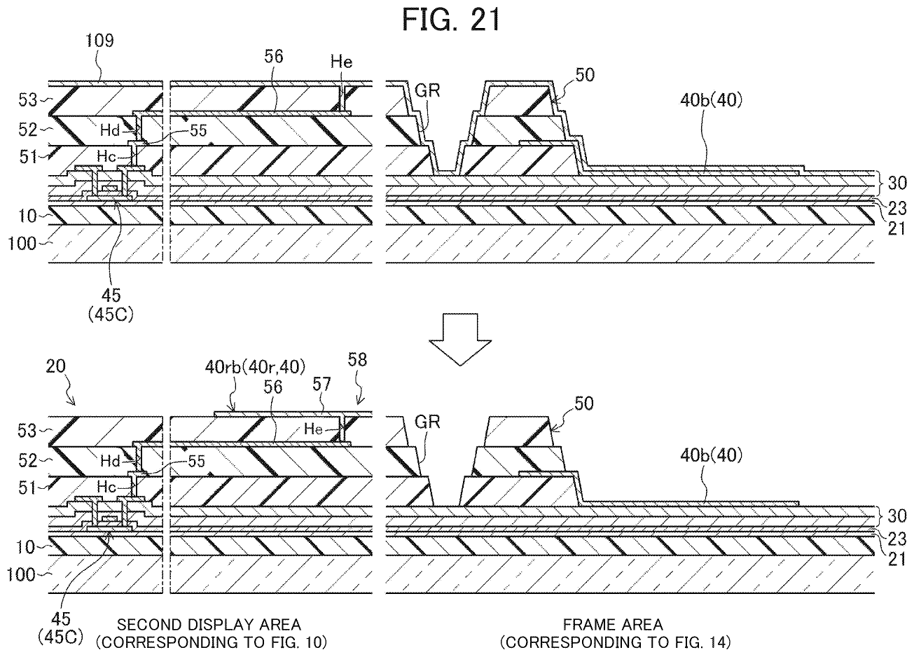

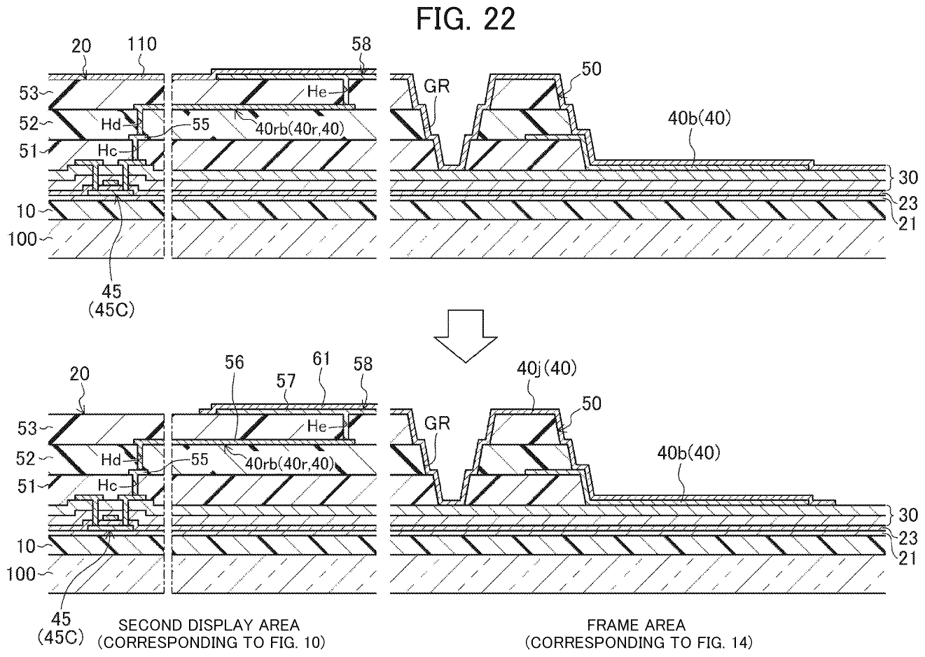

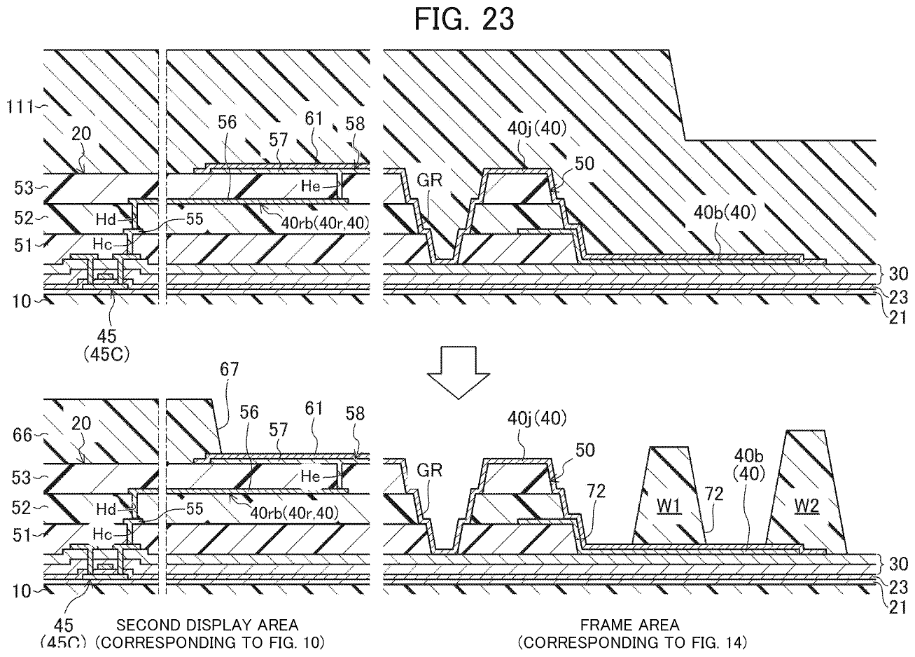

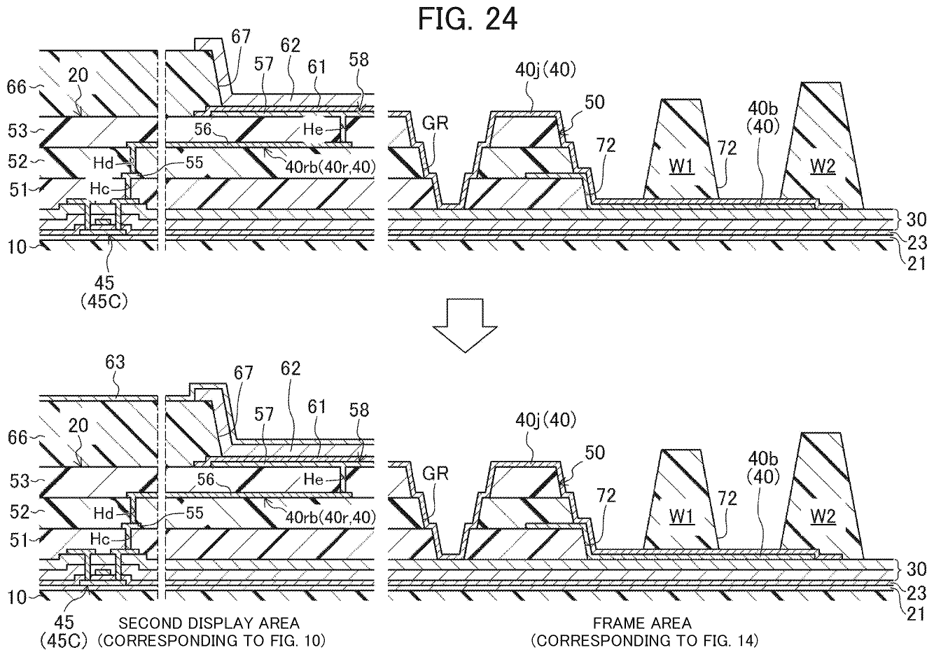

Referring to FIG. 10, the intermediate partial wire 56 in each second connection wire 40rb is connected to a corresponding one of the underlying partial wires 55 in the circuit-arrangement area CA. Then, this intermediate partial wire 56 is drawn out from the circuit-arrangement area CA to the light-emitting element area EA to be connected to the overlying partial wire 57 in the light-emitting element area EA as shown also in FIG. 9. Hence, each second connection wire 40rb extends through a range that stretches across the circuit-arrangement area CA and the light-emitting element area EA and is drawn out from a prescribed one of the TFTs 45 (third TFT 45C) onto the third planarization film 53.

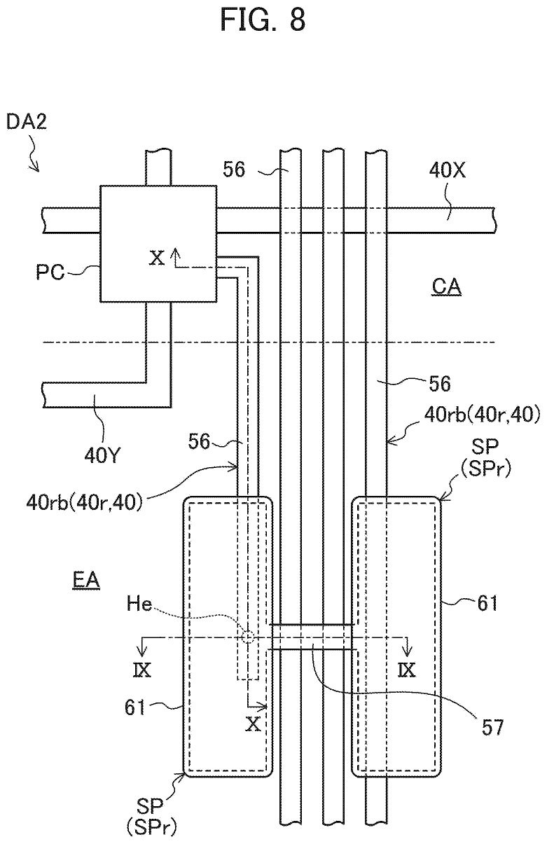

Referring to FIG. 8, in the light-emitting element area EA, some of the intermediate partial wires 56 and some of the overlying partial wires 57 that are not connected to each other intersect with each other in a plan view. The third planarization film 53 is interposed in a position where the intermediate partial wires 56 and the overlying partial wires 57 intersect with each other. Each first electrode 61 in the set of two organic EL elements 65 in the second display area DA2 is provided overlapping a part of the common overlying partial wire 57 and connected to the connection wire 40r.

Referring to FIG. 7, each of the first metal wires 40X corresponding to the plurality of subpixels SP in the second display area DA2 extends via the outside of a group of the organic EL elements 65 disposed in the light-emitting element area EA. Each of these first metal wires 40X extends in the circuit-arrangement area CA, not in the light-emitting element area EA. In addition, each of the second metal wires 40Y corresponding to the plurality of subpixels SP in the second display area DA2 extends via the outside of a group of the organic EL elements 65 disposed in the light-emitting element area EA.

As described here, in the second display area DA2, the first metal wires 40X (the gate lines 40g, the light-emission control lines 40e), the second metal wires 40Y (the source lines 40s, the power supply lines 40p), and the second connection wires 40rb (the intermediate partial wires 56, the overlying partial wires 57) are designed so as to reduce the light transmittance, from the front side to the rear side, of the light-emitting element area EA as little as possible.

In this second display area DA2, the pattern related to the connection wires 40r has a high density. Therefore, the connection wires 40r, particularly the intermediate partial wires 56 and the overlying partial wires 57, are formed with a relatively small line width. The intermediate partial wire 56 has a smaller line width than do other wires underlying the planarization film 50 (e.g., the gate lines 40g, the source lines 40s). In addition, the contact holes, related to the connection wires 40r in the planarization film 50, particularly the fourth contact holes Hd and the fifth contact holes He, are formed with a relatively small opening area in accordance with the line width of the connection wires 40r.

### First Damming Wall and Second Damming Wall

Referring to FIG. 1, the first damming wall W1 and the second damming wall W2 extend parallel to each other along the outer circumference of the display area DA to form a groove-shaped depression 72 along the outer circumference of the display area DA. Specifically, referring to FIGS. 11 to 14, the first damming wall W1 forms the groove-shaped depression 72 between the first damming wall W1 and the multilayered structural portion 58. In addition, another groove-shaped depression 72 is formed between the first damming wall W1 and the second damming wall W2. In other words, these double depressions 72 are provided in the frame area FA so as to surround the display area DA.

Both the first damming wall W1 and the second damming wall W2 have a monolayer structure. Both the first damming wall W1 and the second damming wall W2 are made of the same material, and provided in the same layer, as the edge cover 66. Each of the first damming wall W1 and the second damming wall W2 is designed to have such a height that the liquid material (organic resin material) for the organic layer 82 can be dammed up at least by the second damming wall W2. The second damming wall W2 in accordance with the present example has a greater height than the first damming wall W1 and, for example, is specified to be higher than the first damming wall W1 by at least 0.5 μm.

### First Frame Line and Second Frame Line

Referring to FIG. 11, the first frame line 40a and the second frame line 40b are partially adjacent to each other in the direction in which the depressions 72 extend (first direction Dx). Referring to FIGS. 12 to 14, the first frame line 40a and the second frame line 40b are positioned below one of the organic insulation films in the multilayered structural portion 58 specifically, below the second planarization film 52, and extend to the outside of the planarization film 50.

The first frame line 40a extends onto the first planarization film 51 and further extends toward the display area DA on the first planarization film 51 via the inside of an opening in the trench GR. The first frame line 40a has both ends thereof extending in such a position as to sandwich the trench GR between the first frame line 40a and the second frame line 40b. Meanwhile, the second frame line 40b extends onto the first planarization film 51, but only extends outside the trench GR on the first planarization film 51.

Both the first frame line 40a and the second frame line 40b are provided below the first damming wall W1 and the second damming wall W2 and overlap the first damming wall W1 and the second damming wall W2 in a plan view. Then, both the first frame line 40a and the second frame line 40b are exposed from the planarization film 50, the first damming wall W1, and the second damming wall W2 on the bottom of each depression 72 formed by the first damming wall W1 and the second damming wall W2.

Referring to FIG. 14, a relay line 40j overlaps, and is connected to, the second frame line 40b in a portion that provides three of the sides of the frame area FA, except for the side facing the terminal section TP. The relay line 40j is provided below the first damming wall W1 and the second damming wall W2 so as to cover the second frame line 40b extending to the outside of the planarization film 50. Then, the relay line 40j spreads toward the display area DA so as to cover the outer circumference part of the planarization film 50 including the whole trench GR.

The outer circumference part of the second electrode 63 that is positioned in the frame area FA overlaps the relay line 40j internally to the trench GR and is connected to the second frame line 40b via the relay line 40j. The relay line 40j is also exposed on the bottom of each depression 72 formed by the first damming wall W1 and the second damming wall W2. The first frame line 40a, the second frame line 40b, and the relay line 40j, exposed on the bottom of each depression 72, are covered either only by the first inorganic layer 81 in the sealing film 80 or both by the first inorganic layer 81 and by the second inorganic layer 83.

The first frame line 40a and the second frame line 40b in accordance with the present example is made of the same material, and provided in the same layer, as the underlying partial wires 55. The first frame line 40a, the second frame line 40b, and the underlying partial wires 55 are made of, for example, a metal material such as aluminum (Al), tungsten (W), molybdenum (Mo), tantalum (Ta), chromium (Cr), titanium (Ti), or copper (Cu). These lines and wires may include either a monolayer film or a multilayer film.

For instance, each of the first frame line 40a, the second frame line 40b, and the underlying partial wires 55 includes the second multilayer film 76 shown in FIG. 15. The second multilayer film 76 includes a stack of a fourth metal layer 76a, a fifth metal layer 76b, and a sixth metal layer 76 c. Each fourth metal layer 76 a in the first frame line 40a and the second frame line 40b is formed extending from the surface of the second interlayer insulation film 29 to the surface of the first planarization film 51. The fourth metal layer 76a that provides the underlying partial wires 55 is formed on the surface of the first planarization film 51. The fifth metal layer 76b and the sixth metal layer 76c are stacked in this order on the fourth metal layer 76a.

The fourth metal layer 76a and the sixth metal layer 76c are made of, for example, a metal such as titanium (Ti), molybdenum (Mo), chromium (Cr), and tantalum (Ta). The fourth metal layer 76a and the sixth metal layer 76c may be made of, for example, a metal compound or an alloy. The fifth metal layer 76b is made of, for example, a metal such as aluminum (Al), silver (Ag), or gold (Au). The fifth metal layer 76b may be made of, for example, a metal compound or an alloy.

As a more specific example, the second multilayer film 76 may include a stack of a titanium layer (Ti layer) as the fourth metal layer 76a, an aluminum layer (Al layer) as the fifth metal layer 76b, and a titanium layer (Ti layer) as the sixth metal layer 76c. The second multilayer film 76 may include a titanium alloy layer (Ti alloy layer) in place of the titanium layer (Ti layer). In addition, the second multilayer film 76 may include an aluminum alloy layer (Al alloy layer) in place of the aluminum layer (Al layer). This second multilayer film 76 is preferred in constructing, for example, low-resistance wires and electrodes.

### Workings of Organic EL Display Device

In the organic EL display device 1, in each subpixel SP, a corresponding one of the light-emission control lines 40e is first selected, so that an emission signal representing a non-active state is fed to the third TFT 45C via this light-emission control line 40e. This turns off the third TFT 45C, which in turn renders the organic EL element 65 to a non-emissive state.

Then, one of the gate lines 40g that corresponds to the organic EL element 65 in the non-emissive state is selected, so that a gate signal representing an active state is fed to the first TFT 45A via this gate line 40g. This turns on the first TFT 45A. As the first TFT 45A is turned on, a prescribed voltage corresponding to the source signal transferred via the source line 40s is applied to the second TFT 45B and also written to the capacitor 46.

Thereafter, a corresponding one of the light-emission control lines 40e is selected, so that an emission signal representing an active state is fed to the third TFT 45C. This turns on the third TFT 45C. As the third TFT 45C is turned on, a drive current that is in accordance with the voltage across the second TFT 45B is fed from the power supply line 40p to the organic EL element 65.

In this manner, in the organic EL display device 1, in each subpixel SP, the organic EL element 65 emits light with a luminance that is in accordance with the drive current, to produce an image display. Note that even when the first TFT 45A is turned on, the emission of light by the organic EL element 65 is maintained for each subpixel SP until a gate signal is fed in the next frame because the voltage applied to the gate voltage of the second TFT 45B is retained by the capacitor 46.

In addition, in the organic EL display device 1, external light is transmitted through the second display area DA2 from the front side to the rear side. In response of a user's image-capturing operation, the camera 3 receives the external light transmitted through the second display area DA2 and has the external light converted to an electric signal by the image sensor. The organic EL display device 1 hence captures, on the camera 3, an image with the front side of the display screen as the image subject (subject side).

Method of Manufacturing Organic EL Display Device To manufacture the organic EL display device 1, first, an organic resin material is applied to the surface of a glass substrate 100 and subjected to a baking process. Hence, the substrate layer 10 is formed on the glass substrate 100.

Next, the TFT layer 20, the light-emitting element layer 60, and the sealing film 80 are formed on the substrate layer 10 in this order by, for example, a publicly known film-formation method such as plasma CVD (chemical vapor deposition), sputtering, or vacuum vapor deposition, a publicly known coating method such as spin-coating or slit-coating, or a publicly known patterning method such as photolithography.

Then, the glass substrate 100 is detached from the substrate layer 10 by, for example, projecting a laser beam onto the backside of the substrate layer 10 from the glass substrate 100 side. Subsequently, for example, a polarizer and a cover panel are attached to the surface of the sealing film 80. Furthermore, the wiring board CB is connected to the terminal section TP. Hence, a display control circuit (source driver) is mounted to a panel that is a part of the organic EL display device 1.

The organic EL display device 1 can be manufactured as described in the foregoing.

### Step of Forming TFT Layer

In a step of forming the TFT layer 20, first, the plurality of TFTs 45 and the capacitors 46 are fabricated on the substrate layer 10, which resides on the surface of the glass substrate 100. At this stage, in the frame area FA, the slit SL is formed in a stack body of the basecoat film 21, the gate insulation film 23, and the interlayer insulation film 30, and the first contact hole Ha is formed beforehand in the interlayer insulation film 30.

Next, as shown in the top drawing of FIG. 16, an acrylic-based photosensitive resin is applied by, for example, a publicly known coating method onto the substrate in which the plurality of TFTs 45 and the capacitor 46 are already fabricated, to form a coating film 101 of a photosensitive resin. In the present example, a positive photosensitive resin is used as the photosensitive resin. Subsequently, the coating film 101 of this photosensitive resin is subjected to pre-baking, exposure to light, development, and post-baking. Hence, the first planarization film 51 is formed that has openings for the third contact hole Hc and the trench GR as shown on the bottom drawing of FIG. 16. In addition, the injection layer 70 (not shown) is formed together from the coating film 101 of the same photosensitive resin.

Next, on the substrate in which the first planarization film 51 has been formed, a titanium film (Ti film) or titanium alloy film (Ti alloy film) 102, an aluminum film (Al film) or aluminum alloy film (Al alloy film) 103, and a titanium film (Ti film) or titanium alloy film (Ti alloy film) 104 are formed in this order by, for example, sputtering. Hence, as shown in the top drawing of FIG. 17, a metal stack film 105 is formed so as to cover the first planarization film 51. Subsequently, the metal stack film 105 is patterned by photolithography to form the second frame line 40b and the underlying partial wires 55 as shown on the bottom drawing of FIG. 17. In addition, the first frame line 40a and the overlying draw-out lines 42 (not shown) are formed together from the same the metal stack film 105.

Next, as shown in the top drawing of FIG. 18, an acrylic-based photosensitive resin is applied by, for example, a publicly known coating method onto the substrate in which, for example, the second frame line 40b has been formed, to form a coating film 106 of the photosensitive resin. In the present example, a positive photosensitive resin is used as the photosensitive resin. Subsequently, the coating film 106 of this photosensitive resin is subjected to pre-baking, exposure to light, development, and post-baking. Hence, the second planarization film 52 is formed that has openings for the fourth contact hole Hd and the trench GR as shown on the bottom drawing of FIG. 18.

Next, for example, an indium tin oxide film is formed by, for example, sputtering on the substrate in which the second planarization film 52 has been formed. Hence, a first electrically conductive transparent film 107 is formed so as to cover the second planarization film 52 and the second frame line 40b as shown in the top drawing of FIG. 19. The first electrically conductive transparent film 107 is formed so as to also cover the first frame line 40a (not shown). Subsequently, this first electrically conductive transparent film 107 is patterned by photolithography to form the intermediate partial wires 56 as shown on the bottom drawing of FIG. 19.

In the patterning of the first electrically conductive transparent film 107, either just exposure or under exposure is performed as an exposure process in photolithography, to form the intermediate partial wires 56 with a relatively small line width. “Just exposure” here refers to exposure to light with such an exposure dose as to obtain a resist pattern (mask design value) that exactly matches the dimensions of the opening pattern of the mask used in the exposure. In addition, “under exposure” refers to exposure to light with a lower exposure dose (exposure time) than just exposure.

Next, as shown in the top drawing of FIG. 20, an acrylic-based photosensitive resin is applied by, for example, a publicly known coating method onto the substrate in which the intermediate partial wires 56 have been formed, to form a coating film 108 of the photosensitive resin. In the present example, a positive photosensitive resin is used as the photosensitive resin. Subsequently, the coating film 108 of this photosensitive resin is subjected to pre-baking, exposure to light, development, and post-baking. Hence, the third planarization film 53 is formed that has openings for the fifth contact hole He and the trench GR as shown on the bottom drawing of FIG. 20. The planarization film 50 is hence provided.

Next, for example, an indium tin oxide film is formed by, for example, sputtering on the substrate in which the planarization film 50 has been formed. Hence, a second electrically conductive transparent film 109 is formed so as to cover the third planarization film 53 and the second frame line 40b as shown in the top drawing of FIG. 21. The second electrically conductive transparent film 109 is formed so as to also cover the first frame line 40a (not shown). Subsequently, this second electrically conductive transparent film 109 is patterned by photolithography to form the overlying partial wires 57 as shown on the bottom drawing of FIG. 21. In the patterning of the second electrically conductive transparent film 109, either just exposure or under exposure is similarly performed as an exposure process in photolithography. The multilayered structural portion 58 is hence provided.

Thereafter, the substrate in which the overlying partial wires 57 have been formed is subjected to annealing at a temperature of, for example, 200° C. to 250° C. for 30 minutes to 120 minutes. This annealing crystallizes the intermediate partial wires 56 and the overlying partial wires 57. The electrical conduction and transparence of the intermediate partial wires 56 and the overlying partial wires 57 are hence enhanced. In addition, the crystallization imparts, to the overlying partial wires 57, resistance to a PAN-based etchant used in the process of patterning performed later on the first electrodes 61.

The TFT layer 20 can be hence formed.

### Step of Forming Light-Emitting Element Layer

In a step of forming the light-emitting element layer 60, first, an indium tin oxide film (ITO film), a silver film (Ag film), and another indium tin oxide film (ITO film) are formed in this order by, for example, sputtering, on the substrate in which the TFT layer 20 has been formed. Hence, a conductive film stack 110 is formed so as to cover the overlying partial wires 57, the third planarization film 53, and the second frame line 40b as shown in the top drawing of FIG. 22. Subsequently, the conductive film stack 110 is patterned by photolithography to form the first electrodes 61 and the relay line 40j as shown on the bottom drawing of FIG. 22.

In the patterning of the conductive film stack 110, a resist is formed where the first electrodes 61 are provided, and wet etching is performed using the resist as a mask. In this wet etching, a PAN-based etchant that is a mixture of phosphorus acid, nitric acid, and acetic acid is used as an etchant. In so doing, the overlying partial wires 57 are exposed to the PAN-based etchant. However, the overlying partial wires 57 are not corroded or unlikely to be corroded by this etchant because the overlying partial wires 57 are crystallized in advance and therefore resistant.

In addition, in the patterning of the conductive film stack 110, just exposure or under exposure is similarly performed as an exposure process in photolithography, for their advantages in reducing the takt time. Note that the first electrodes 61 are a relatively large pattern, and for this reason, over exposure may be performed as an exposure process in photolithography. “Over exposure” here refers to exposure to light with a higher exposure dose (exposure time) than just exposure.

Next, as shown in the top drawing of FIG. 23, an acrylic-based photosensitive resin is applied by a publicly known coating method onto the substrate in which, for example, the first electrodes 61 have been formed, to form a photosensitive-resin coating film 111. In the present example, a positive photosensitive resin is used as the photosensitive resin. Subsequently, this photosensitive-resin coating film 111 is subjected to pre-baking, exposure to light, development, and post-baking. Hence, the edge cover 66 including the photospacers 68, the first damming wall W1, and the second damming wall W2 are formed as shown on the bottom drawing of FIG. 23.

In so doing, in the exposure process, light is projected onto the photosensitive-resin coating film 111 via a photomask to cause the photosensitive resin to react with the light. This photomask is a grayscale mask such as a halftone mask or a gray tone mask. The grayscale mask is configured so as to pass light onto unwanted parts of the photosensitive-resin coating film, as to totally block light above the parts where the photospacers are formed and the parts where the second damming wall W2 is formed, and as to partially block light above the parts where the remaining edge cover 66 is formed and the parts where the remaining, first damming wall W1 is formed. The use of this grayscale mask enables forming the edge cover 66 including the photospacers 68, the first damming wall W1, and the second damming wall W2 from same photosensitive-resin coating film 111 so that there exists a difference in height between the first damming wall W1 and the second damming wall W2.

Next, a hole injection layer, a hole transport layer, a light-emitting layer, an electron transport layer, and an electron injection layer are sequentially formed on the substrate in which, for example, the edge cover 66 has been formed, by, for example, vacuum vapor deposition using a film-formation mask called an FMM (fine metal mask) which enables patterning on the subpixel-to-subpixel basis. Hence, the organic EL layer 62 is formed on the individual first electrodes 61 in the openings 67 in the edge cover 66.

Thereafter, at least one conductive film selected from an indium tin oxide film (ITO film), an indium zinc oxide film (IZO film), and a magnesium-silver alloy film (MgAg film) is formed on the substrate in which the organic EL layer 62 has been formed, by, for example, vacuum vapor deposition using a film-formation mask called a CMM (common metal mask) which enables patterning on the display panel-to-display panel basis. Hence, the second electrode 63 is formed so as to overlap each organic EL layer 62.

The light-emitting element layer 60 can be formed in this manner.

### Step of Forming Sealing Film

In a step of forming the sealing film 80, first, either a monolayer inorganic insulation film or a stack of a plurality of inorganic insulation films is formed by, for example, plasma CVD using a film-formation mask (CMM) on the substrate in which the light-emitting element layer 60 has been formed. Hence, the first inorganic layer 81 is formed so as to cover the second electrode 63, the first damming wall W1, and the second damming wall W2.

Next, a liquid organic insulating material is applied by, for example, inkjet printing to a region, internal to the first damming wall W1, on the substrate in which the first inorganic layer 81 has been formed, to form a coating film of the liquid material. The applied liquid material wets and spreads toward the outer circumference of the substrate, but is dammed up by the first damming wall W1 and, where necessary, by the second damming wall W2. Subsequently, the liquid-material coating film is subjected to, for example, ultraviolet light projection, heating, or a like curing process. Hence, the organic layer 82 is formed so as to cover the display area DA.

Thereafter, either a monolayer inorganic insulation film or a stack of a plurality of inorganic insulation films is formed by, for example, plasma CVD using a film-formation mask (CMM) on the substrate in which the organic layer 82 has been formed. Hence, the second inorganic layer 83 is formed so as to cover the organic layer 82, the first damming wall W1, and the second damming wall W2.

The sealing film 80 can be formed in this manner.

### Features of Embodiment

In the organic EL display device 1 in accordance with this embodiment, the first damming wall W1 and the second damming wall W2 are made of the same material, and provided in the same layer, as the edge cover 66. The edge cover 66 is provided on the multilayered structural portion 58. In the manufacture of this organic EL display device 1, both the first damming wall W1 and the second damming wall W2 are formed by forming the first planarization film 51, the underlying partial wires 55, the second planarization film 52, the intermediate partial wires 56, the third planarization film 53, and the overlying partial wires 57 in this order after the multilayered structural portion 58 is provided.

Incidentally, when the organic EL display device 1 is configured so that at least a part of the first damming wall W1 and the second damming wall W2 is formed before the multilayered structural portion 58 is provided, specifically, as an example, when each of the first damming wall W1 and the second damming wall W2 is a stack of a plurality of wall layers, and at least one of the wall layers is made of the same material, and provided in the same layer, as the first planarization film 51, the second planarization film 52, or the third planarization film 53, a film residue RS of the resist used in the patterning of partial wires in the connection wires 40r tends to be produced in the depressions 72 formed by these wall layers in the manufacture the organic EL display device 1.

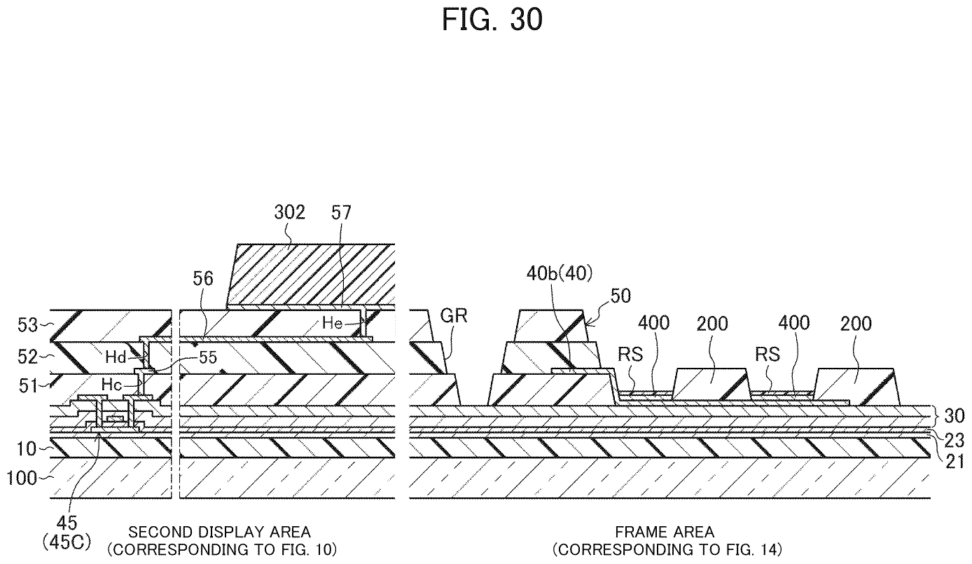

For instance, when one of the plurality of wall layers (wall layer 200) in the first damming wall W1 and the second damming wall W2 is made of the same material, and provided in the same layer, as the second planarization film 52 as shown in FIG. 29, the film residue RS of a resist 300 used in the patterning of the intermediate partial wires 56 could undesirably be produced in the depressions 72 in the formation of the intermediate partial wires 56. When this is the case, the film residue RS of the resist 300 could similarly be produced in the depressions 72 in the formation of the overlying partial wires 57. In addition, when one of the plurality of wall layers (wall layer 200) in the first damming wall W1 and the second damming wall W2 is made of the same material, and provided in the same layer, as the third planarization film 53 as shown in FIG. 30, the film residue RS of a resist 302 used in the patterning of the overlying partial wires 57 could undesirably be produced in the depressions 72 in the formation of the overlying partial wires 57.

As the film residue RS of a resist is produced in this manner in the depressions 72 formed by the wall layer 200, a conductive residue 400 is left in the depressions 72. Under these circumstances, the first frame line 40a and the second frame line 40b, exposed on the bottoms of the depressions 72 formed by the first damming wall W1 and the second damming wall W2, are defectively short-circuited via the conductive residue 400. To eliminate the resist film residue RS in the depressions 72, over exposure may be employed in the exposure process in forming the resist for the patterning of, for example, the intermediate partial wires 56 and the overlying partial wires 57, in order to completely expose the photosensitive resin having reached these depressions 72 to light down to the bottoms of the depressions 72. However, this over exposure thins down, for example, the intermediate partial wires 56 and the overlying partial wires 57 and hence renders it difficult to form, for example, the intermediate partial wires 56 and the overlying partial wires 57 with a required line width, which in turn renders it impossible to provide the connection wires 40r in high density in the second display area DA2.

In contrast, in the organic EL display device 1 in accordance with this embodiment, when the underlying partial wires 55, the intermediate partial wires 56, and the overlying partial wires 57 are formed, the first damming wall W1 and the second damming wall W2 are not present, and therefore the depressions 72 are not present. Accordingly, the problem can be solved that the film residue RS of the resist used in the patterning of the underlying partial wires 55, the intermediate partial wires 56, and the overlying partial wires 57 is produced in the depressions 72. Hence, no conductive residue 400 remains in the depressions 72, which enables restraining the short-circuiting of the first frame line 40a and the second frame line 40b exposed on the bottoms of the depressions 72. Then, the exposure process does not need to employ over exposure in forming the resist used in the patterning of the intermediate partial wires 56 and the overlying partial wires 57, and the intermediate partial wires 56 and the overlying partial wires 57 can be formed satisfactorily with a relatively small line width, which in turn renders it possible to provide the connection wires 40r in high density in the second display area DA2.

In addition, in the organic EL display device 1 in accordance with this embodiment, both the second frame line 40b and the relay line 40j are provided below the first damming wall W1 and the second damming wall W2. This particular configuration allows the relay line 40j to be provided overlapping the second frame line 40b even in regions overlapping the first damming wall W1 and the second damming wall W2 in a plan view. Hence, the connection area of the relay line 40j and the second frame line 40b can be suitably ensured.

### First Variation Example

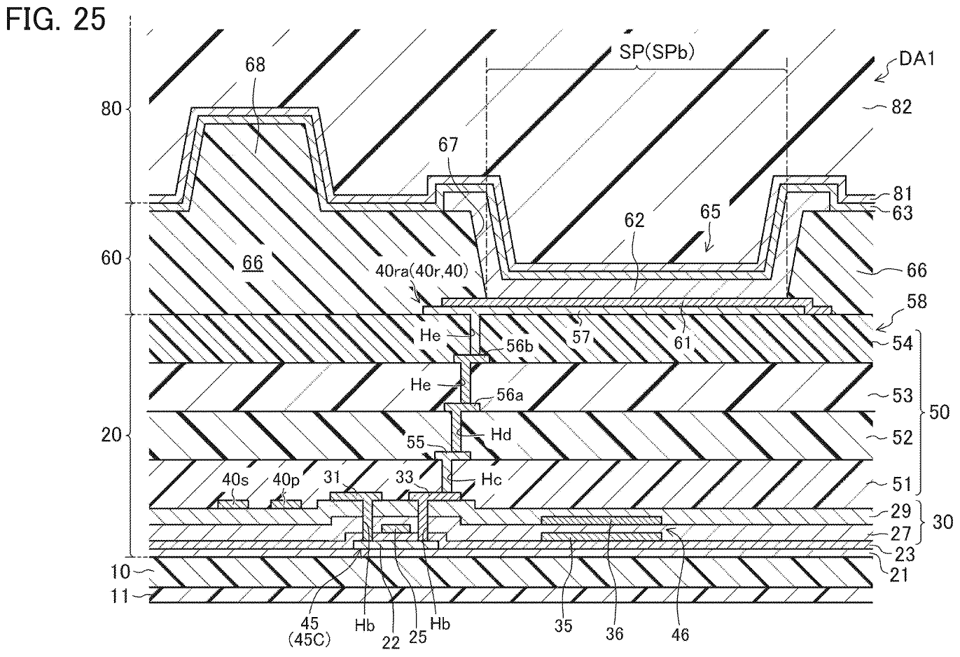

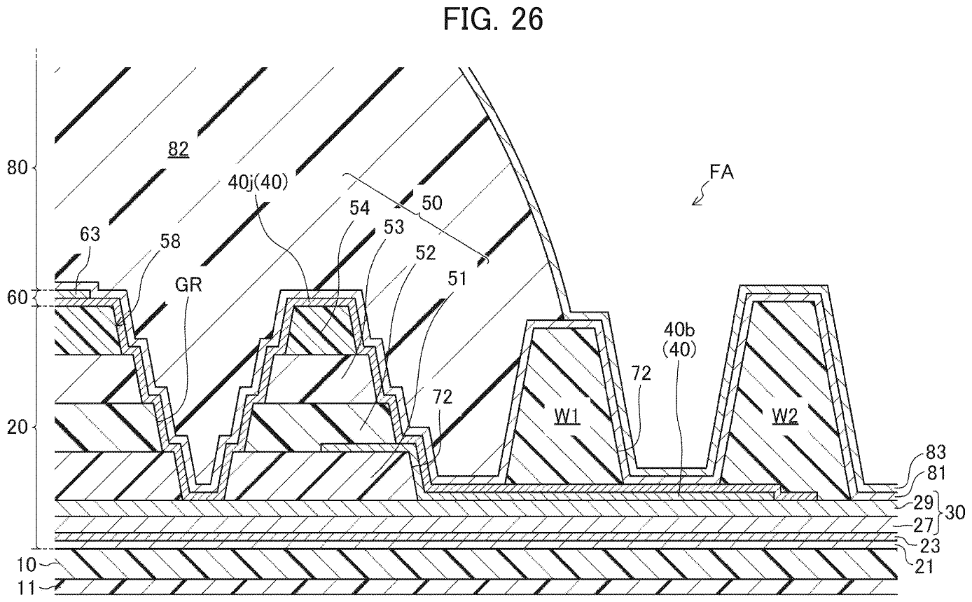

The multilayered structural portion 58 may have a four-layered structure including four layers of organic insulation films. In other words, referring to FIGS. 25 and 26, the planarization film 50 may include a fourth planarization film 54, as well as the first planarization film 51, the second planarization film 52, and the third planarization film 53. The fourth planarization film 54 is an example of a first organic insulation film. The fourth planarization film 54 is stacked on the third planarization film 53 and spreads all across the entire display area DA together with the first planarization film 51, the second planarization film 52, and the third planarization film 53. The fourth planarization film 54 is made of a photosensitive resin and hence transparent to light, similarly to, for example, the first planarization film 51.

When the planarization film 50 includes the fourth planarization film 54, the connection wires 40 r includes the underlying partial wires 55, first intermediate partial wires 56a, second intermediate partial wires 56b, and the overlying partial wires 57. The underlying partial wires 55 are provided on the first planarization film 51 in a similar configuration to the foregoing embodiment. The first intermediate partial wires 56a are provided insularly on the second planarization film 52 and positioned below the third planarization film 53. The first intermediate partial wires 56a are connected to the underlying partial wires 55 via the fourth contact holes Hd.

The second intermediate partial wires 56b are provided insularly on the third planarization film 53 and positioned below the fourth planarization film 54. The second intermediate partial wires 56b are connected to the first intermediate partial wires 56a via the fifth contact holes He formed in the third planarization film 53. The overlying partial wires 57 are provided on the fourth planarization film 54 in a similar configuration to the foregoing embodiment. The fourth planarization film 54 has a sixth contact hole Hf formed therein for each of the pixel circuits PC. The sixth contact hole Hf runs through to the second intermediate partial wire 56b. The overlying partial wire 57 is connected to a corresponding one of the second intermediate partial wires 56b via the sixth contact hole Hf.

In the organic EL display device 1 in accordance with this first variation example, the planarization film 50 has a four-layered structure, and the connection wire includes four partial wires. This particular configuration enables increasing the layout freedom of the pattern for the connection wires 40r in the second display area DA2. With an increase in the layered structure of the planarization film 50, the depressions 72 formed by the first damming wall W1 and the second damming wall W2 increase its depth, and the above-described resist film residue RS is more likely to be produced. Thus, the technique of the present disclosure, capable of solving the problems of this resist film residue RS, is effective also in the organic EL display device 1 in accordance with this first variation example.

### Second Variation Example

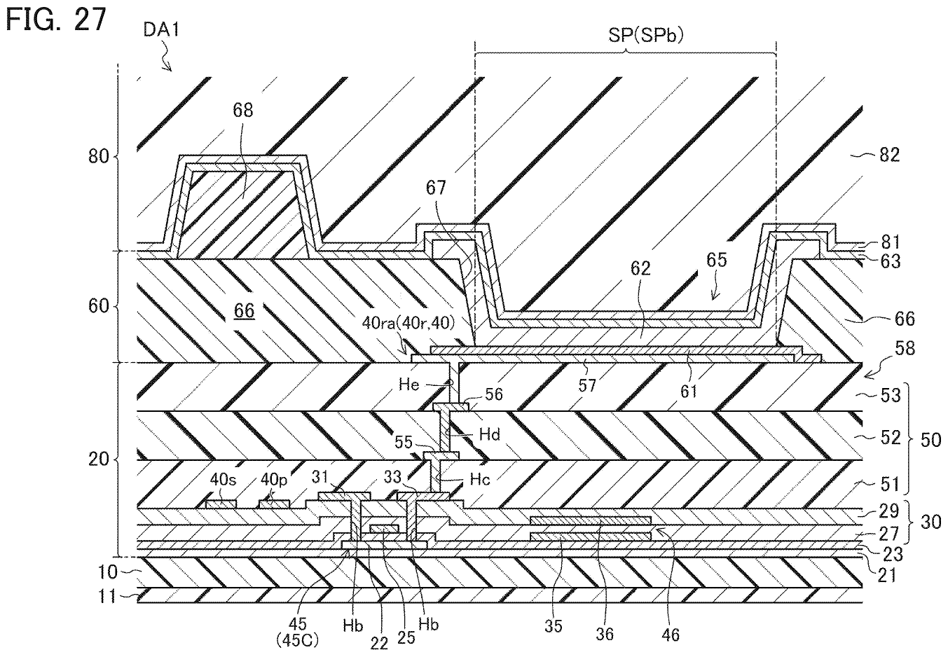

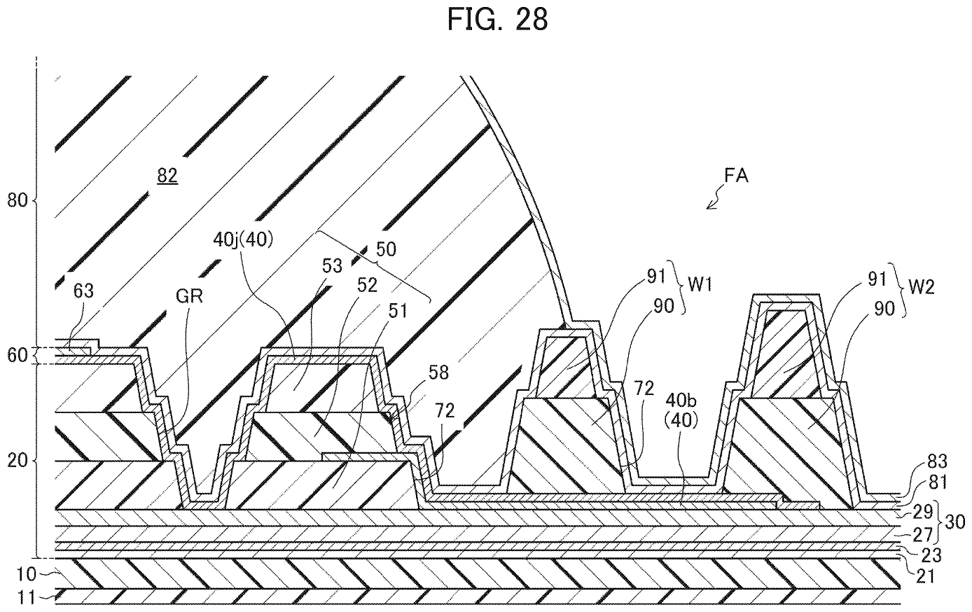

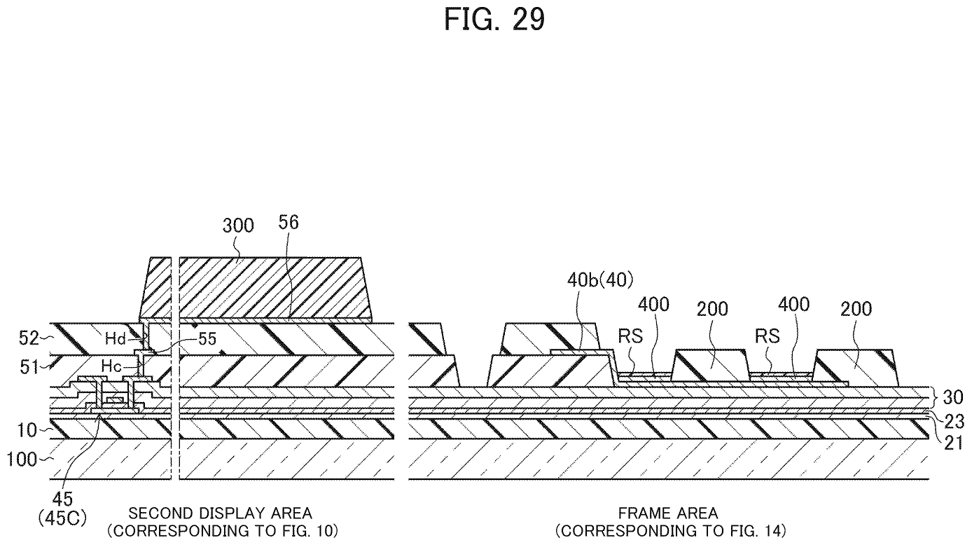

Referring to FIG. 27, the photospacers 68 may be provided separately from the edge cover 66. When this is the case, each of the first damming wall W1 and the second damming wall W2 may include a stack of a first wall layer 90 and a second wall layer 91 as shown in FIG. 28. The first wall layer 90 is made of the same material, and provided in the same layer, as the edge cover 66. The second wall layer 91 is made of the same material, and provided in the same layer, as the photospacer 68. As described here, the first damming wall W1 and the second damming wall W2 may have a layered structure.

Note that the first damming wall W1 and the second damming wall W2 may each have a stack of three or more wall layers (not shown). In addition, the first damming wall W1 and the second damming wall W2 may include mutually different numbers of wall layers. As an example, the first damming wall W1 may include only the first wall layer 90, and the second damming wall W2 may include a stack of the first wall layer 90 and the second wall layer 91.

### Other Embodiments

The aforementioned embodiment discusses, as an example, the organic EL display device 1 including the first damming wall W1 and the second damming wall W2 as wall bodies, which is merely illustrative. Alternatively, as the wall body, only a single damming wall may be provided, and three or more damming walls may be provided. In addition, the wall body may be provided for a purpose other than the damming of the liquid material which will form the organic layer 82, for example, for a purpose of restraining cracks from growing in the inorganic layer in the sealing film 80 from the outer circumference side.

The aforementioned embodiment assumes that the first damming wall W1 and the second damming wall W2 are made of the same material, and provided in the same layer, as the edge cover 66, which is merely illustrative. Alternatively, the first damming wall W1 and the second damming wall W2 may be made of the same material, and provided in the same layer, as any member other than the edge cover 66 so long as the member is an organic insulation film (second organic insulation film) positioned above the multilayered structural portion 58.

The aforementioned embodiment assumes that the first damming wall W1 is higher than the second damming wall W2, which is merely illustrative. Alternatively, for example, the first damming wall W1 and the second damming wall W2 may have the same height. The first damming wall W1 and the second damming wall W2 may have either the same width or different widths.

The aforementioned embodiment assumes that the first frame line 40a and the second frame line 40b are made of the same material, and provided in the same layer, as the underlying partial wires 55, which is merely illustrative. Alternatively, for example, the first frame line 40a and the second frame line 40b may be made of the same material, and provided in the same layer, as, for example, the source lines 40s and/or the first terminal electrodes 31. In addition, the first frame line 40a and the second frame line 40b may include a stack of a first wiring layer and a second wiring layer. The first wiring layer is made of the same material, and provided in the same layer, as, for example, the source lines 40s. The second wiring layer is made of the same material, and provided in the same layer, as the underlying partial wires 55.

The aforementioned embodiment discusses an example where the multilayered structural portion 58 has a three-layered insulation structure, and the first variation example discusses an example where the multilayered structural portion 58 has a four-layered insulation structure, which is merely illustrative. Alternatively, the multilayered structural portion 58 may have a two-layered insulation structure including only two layers of first organic insulation films and may have multilayered insulation structure including five or more layers of first organic insulation films.

The aforementioned embodiment discusses an example where the organic EL display device 1 includes the first frame line 40a as the first wiring line and the second frame line 40b as the second wiring line, which is merely illustrative. Alternatively, the first wiring line and the second wiring line may be wires other than power trunk lines so long as these wires transfer (supply), for example, mutually different signals and electrical potentials.

The aforementioned embodiment assumes that each two of the plurality of organic EL elements 65 disposed in the light-emitting element area EA makes up a single set so that the organic EL elements 65 in each set are connected to each other via one of the overlying partial wires 57, which is merely illustrative. Alternatively, each three or more of the plurality of organic EL elements 65 disposed in the light-emitting element area EA may make up a single set so that the organic EL elements 65 in each set can be connected to each other via one of the overlying partial wires 57.

In addition, each two or more of the plurality of organic EL elements 65 disposed in the light-emitting element area EA does not need to make up a single set. In other words, the plurality of organic EL elements 65 disposed in the light-emitting element area EA do not need to be connected to each other and may be individually controlled. When this is the case, the circuit-arrangement area CA includes a separate pixel circuit PC for each organic EL element 65, and each organic EL element 65 is connected to a different pixel circuit PC via one of the connection wires 40r.

The aforementioned embodiment assumes that the organic EL layer 62 is provided individually for each subpixel SP, which is merely illustrative. Alternatively, the organic EL layer 62 may be provided commonly to, and contiguously across, the plurality of subpixels SP. When this is the case, the organic EL display device 1 may reproduce shades of color in each subpixel SP by, for example, including a color filter.

The aforementioned embodiment assumes that each pixel PX includes three-color subpixels SP, which is merely illustrative. Alternatively, the subpixels SP in each pixel PX may have four or more colors. In addition, the aforementioned embodiment assumes that the three-color subpixels SP in each pixel PX are arranged in stripes, which is merely illustrative. Alternatively, the plurality of subpixels SP may be arranged in any other layout such as a PenTile layout.

The aforementioned embodiment assumes that the plurality of TFTs 45 in the pixel circuit PC include three TFTs, that is, the first TFT 45A, the second TFT 45B, and the third TFT 45C, which is merely illustrative. Alternatively, the number of the TFTs 45 in the pixel circuit PC may be two or less and may be four or more. In addition, the TFTs 45 may have a bottom gate structure.

The aforementioned embodiment assumes that the first electrode 61 functions as an anode and that the second electrode 63 functions as a cathode, which is merely illustrative. Alternatively, the organic EL display device 1 may be configured so that the first electrode 61 functions as a cathode and that the second electrode 63 functions as an anode. When this is the case, the organic EL layer 62 has a reverse layered structure.

The aforementioned embodiment assumes that the organic EL layer 62 has a five-layered structure including a hole injection layer, a hole transport layer, a light-emitting layer, an electron transport layer, and an electron injection layer, which is merely illustrative. Alternatively, the organic EL layer 62 may have a three-layered structure including a hole injection and transport layer, a light-emitting layer, and an electron transport and injection layer and may have any other layered structure.

The aforementioned embodiment assumes that the organic EL display device 1 includes the substrate layer 10 as the substrate, which is merely illustrative. Alternatively, this substrate may be a substrate composed of any material such as a plastic substrate composed of polyethylene terephthalate (PET) or a glass substrate, so long as the substrate is transparent to light.

The aforementioned embodiment discusses, as an example, the camera 3 as an electronic component combined with the organic EL display device 1, which is merely illustrative. Alternatively, this electronic component may be any other electronic component such as a fingerprint sensor, a face recognition sensor, or a luminance sensor, so long as the electronic component is disposed in a position overlapping the second display area DA2 on the rear side of the organic EL display device 1 and utilizes the light transmitted through the display area DA.

The aforementioned embodiment discusses the organic EL display device 1 as an example of a display device in accordance with the present disclosure, which is merely illustrative. Alternatively, the technique of the present disclosure is applicable to display devices including a plurality of light-emitting elements. An example of such a display device is quantum-dot display device including QLEDs (quantum-dot light-emitting diodes) which are light-emitting elements using a quantum-dot-containing layer. Moreover, the technique of the present disclosure is also applicable to, for example, liquid crystal display devices and plasma display devices.

Preferred embodiments have been described so far to illustrate the technology disclosed here. The technology disclosed here is however not limited to these embodiments and variation examples and applicable also to other embodiments that may involve, for example, suitable modification, replacement, addition, and/or omission. It will be understood by those skilled in the art that various modifications can be made to the above-described embodiment without departing from the spirit of the technology of the present disclosure and that such modifications also fall within the scope of the technology of the present disclosure.

### INDUSTRIAL APPLICABILITY

As described above, the present disclosure is useful in display devices.

1: A display device having: a display area where an image is displayed; and a frame area provided around the display area,
the display device comprising, in the display area:
a plurality of light-emitting elements provided correspondingly to a plurality of subpixels;
a plurality of pixel circuits configured to control emission of light by the plurality of light-emitting elements; and
connection wires configured to connect the plurality of light-emitting elements and the plurality of pixel circuits respectively, wherein
the connection wires include a plurality of partial wires formed in mutually different layers via a first organic insulation film of an organic insulating material,
the first organic insulation film and a partial wire including the plurality of partial wires are alternately stacked to provide a multilayered structural portion, and
a second organic insulation film of an organic insulating material is provided on the multilayered structural portion,
the display device further comprising, in the frame area:
a wall body configured to form a groove-shaped depression along an outer circumference of the display area; and
a first wiring line and a second wiring line exposed on a bottom of the depression, wherein
the wall body is made of a same material, and provided in a same layer, as the second organic insulation film.

2: The display device according to claim 1, wherein
each of the plurality of light-emitting elements includes an individually separated, first electrode provided on the multilayered structural portion, and
an edge cover is provided as the second organic insulation film in the display area so as to partition the plurality of first electrodes and cover outer edges of the plurality of first electrodes.

3: The display device according to claim 1, wherein each of the first wiring line and the second wiring line is a power trunk line configured to apply a voltage to the plurality of light-emitting elements.

4: The display device according to claim 3, wherein
each of the plurality of light-emitting elements includes:
an individually separated, first electrode provided on the multilayered structural portion;
an electroluminescence layer provided on the first electrode; and
a second electrode overlapping the first electrode via the electroluminescence layer, and
the second electrode is provided as a contiguous common film so as to spread across the plurality of subpixels and connected to the second wiring line in a region where the wall body is provided.

5: The display device according to claim 1, wherein the multilayered structural portion includes three or more layers of the first organic insulation film.

6: The display device according to claim 1, wherein the wall body has a monolayer structure.

7: The display device according to claim 1, wherein the wall body forms the depression between the wall body and the multilayered structural portion.

8: The display device according to claim 1, wherein
the wall body includes a first wall body and a second wall body extending parallel to each other along the outer circumference of the display area, and
the depression is formed between the first wall body and the second wall body.

9: The display device according to claim 1, further comprising, in a position on a rear side overlapping the display area in a plan view, an electronic component configured to utilize external light transmitted through the display area, wherein
the display area includes:
a first display area; and
a second display area provided internal to the first display area and configured to transmit light utilized by the electronic component, and
some of the plurality of partial wires are made of a conductive, transparent material that transmits light.

10: The display device according to claim 9, wherein the conductive, transparent material is indium tin oxide.

11: The display device according to claim 9, wherein
the second display area includes a light-emitting element area in which the plurality of light-emitting elements are disposed,
the plurality of pixel circuits configured to control emission of light by the plurality of light-emitting elements disposed in this light-emitting element area are disposed around the light-emitting element area, and
the plurality of partial wires provided in the mutually different layers intersect with each other via the first organic insulation film in the light-emitting element area.

12: The display device according to claim 9, wherein the electronic component is a camera.

13: The display device according to claim 1, further comprising, in the display area, a sealing film configured to seal the plurality of light-emitting elements, wherein
the sealing film includes an organic layer formed by applying a liquid material,
the wall body is a damming wall shaped like a frame so as to surround the display area, and
the organic layer is provided internal to the damming wall.

14: The display device according to claim 1, wherein the plurality of light-emitting elements are organic electroluminescence elements.
